(19) United States
(12) Patent Application Publication
(10) Pub. No.: US 2024/0384122 A1
(43) Pub. Date: Nov. 21, 2024

(54) COMPOSITION

(71) Applicant: Merck Patent GmbH, Darmstadt (DE)

(72) Inventors: Elizaveta KOSSOY, Jerusalem (IL); Yaron AVIV, Jerusalem (IL); Ravit YAKOBI, Jerusalem (IL); Artyom SEMYONOV, Jerusalem (IL); Evgeniy MERVINETSKY, Jerusalem (IL)

(21) Appl. No.: 18/564,648

(22) PCT Filed: May 31, 2022
(86) PCT No.: PCT/EP2022/064672

§ 371 Date: Nov. 28, 2023

(30) Foreign Application Priority Data
Jun. 1, 2021 (EP) 21177021.9

(51) Int. Cl. C09D 11/50; B82Y 20/00; B82Y 40/00; C09D 11/037; C09D 11/101; C09D 11/107; C09D 11/322; C09K 11/02; H10K 59/38

(52) U.S. Cl. CPC C09D 11/50; C09D 11/037; C09D 11/101; C09D 11/107; C09D 11/322; C09K 11/025; H10K 59/38; B82Y 20/00; B82Y 40/00

(57) ABSTRACT

The present invention relates to a composition comprising at least one light emitting moiety.

### FIELD OF THE INVENTION

The present invention relates to a composition, preferably being of a photocurable composition, comprising at least one light emitting moiety; a layer, a color conversion device, process for fabricating a color conversion device, an optical device containing at least one color conversion device, method for fabricating a color conversion device and use of a composition.

### BACKGROUND ART

WO 2017/054898 A1 describes a composition comprising red emission type nanocrystals, wetting and dispersing agent, propylene glycol monomethyl ether acetate as a solvent, an acryl polymer mixture including an acrylic unit including an acid group and a silane modified acrylic unit.

WO 2019/002239 A1 discloses a composition comprising a semiconducting light emitting nanoparticles, a polymer and a (meth)acrylate such as 1.4. cyclohexanedimethanol-monoacrylate having high viscosity around 90 cp.

### PATENT LITERATURE

1. WO 2017/054898 A1
2. WO 2019/002239 A1

### SUMMARY OF THE INVENTION

However, the inventors newly have found that there are still one or more of considerable problems for which improvement is desired, as listed below. improved homogeneous dispersion of light emitting moieties in the composition, improved homogeneous dispersion of scattering particles in the composition, preferably improved homogeneous dispersion of both light emitting particles and scattering particles, more preferably improved homogeneous dispersion of light emitting moieties and/or scattering particles without solvent; composition having lower viscosity suitable for inkjet printing, preferably a composition which can keep lower viscosity even if it is mixed with high loading of light emitting moieties and/or scattering particles, even more preferably without solvent; composition having lower vapor pressure for large area uniform printing; a new composition realizing no or reduced residue around ink jet printing nozzle during/after ink jet printing, improved QY and/or EQE of light emitting moieties in the composition, improved QY and/or EQE of light emitting moieties after printing; improved thermal stability; easy printing without clogging at a printing nozzle; easy handling of the composition, improved printing properties; simple fabrication process; improved absorbance of blue light; improved solidity of a later made from the composition after inkjet printing.

The inventors aimed to solve one or more of the above-mentioned problems.

Then it was found a novel composition, preferably it is being of a photocurable composition, comprising at least;
i) a reactive monomer, preferably said monomer having one or more of functional groups, more preferably it is a(meth)acrylate monomer;
ii) a light emitting moiety; and
iii) a chemical compound comprising at least one group selected from unsaturated straight-chain alkyl group having carbon atoms 1 to 45; unsaturated or saturated straight-chain alkyl group having carbon atoms 1 to 80, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
wherein said chemical compound is not a polymer.

In another aspect, the present invention relates to a composition comprising a polymer derived or derivable from one or more of the reactive monomers of the composition of the present invention.

In another aspect, the present invention relates to a process of fabricating the composition of the present invention comprising at least; essentially consisting of, or consisting of, the following steps Y1 and Y2, preferably in this sequence or Y3;
Y1) mixing at least one light emitting moiety and a reactive monomer to form a 1^{st} composition;
Y2) mixing the 1^{st} composition with a chemical compound comprising at least one group selected from unsaturated straight-chain alkyl group having carbon atoms 1 to 45; unsaturated or saturated straight-chain alkyl group having carbon atoms 1 to 80, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45; wherein said chemical compound is not a polymer; or
Y3) mixing at least one light emitting moiety and a reactive monomer with a chemical compound comprising at least one group selected from unsaturated straight-chain alkyl group having carbon atoms 1 to 45; unsaturated or saturated straight-chain alkyl group having carbon atoms 1 to 80, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
wherein said chemical compound is not a polymer.

In another aspect, the present invention relates to use of the composition of the present invention, in an electronic device, optical device, sensing device or in a biomedical device or for fabricating an electronic device, sensing device, optical device or a biomedical device.

In another aspect, the present invention relates to a layer containing a composition of the present invention.

In another aspect, the present invention relates to a layer containing at least, essentially consisting of or consisting of;
I) a (meth)acrylate polymer, preferably it is obtained or obtainable from the (meth)acrylate monomers in the composition of the present invention;
II) a light emitting moiety; and
III) a chemical compound comprising at least one group selected from unsaturated straight-chain alkyl group having carbon atoms 1 to 45; unsaturated or saturated straight-chain alkyl group having carbon atoms 1 to 80, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
wherein said chemical compound is not a polymer.

In another aspect, the present invention relates to a process of fabricating the layer of the present invention, wherein the process comprises at least, essentially consisting of or consisting of the following steps;
I) providing a composition of the present invention onto a substrate, preferably
II) curing the composition, preferably said curing is performed by photo irradiation and/or thermal treatment.

In another aspect, the present invention relates to a layer obtained or obtainable from the process.

In another aspect, the present invention further relates to a color conversion device (100) comprising at least, essentially consisting of or consisting of, a 1^{st} pixel (161) partly or fully filled with the layer of the present invention, comprising at least a matrix material (120) containing a light emitting moiety (110), and a bank (150) comprising at least a polymer material, preferably the color conversion device (100) further contains a supporting medium (170).

In another aspect, the present invention further relates to use of the composition of the present invention for fabricating the layer of the present invention or the device (100) of the present invention.

In another aspect, the present invention relates to a method for fabricating a color conversion device (100) of the present invention containing at least, essentially consisting of or consisting of, the following steps, preferably in this sequence;
Xi) Providing a bank composition onto a surface of a supporting medium
Xii) Curing the bank composition,
Xiii) Applying photo-patterning to the cured said composition to fabricate bank and a patterned pixel region,
Xiv) Providing the composition of the present invention to at least one pixel region, preferably by ink-jetting,
Xv) Curing the composition, preferably said color conversion device (100) further contains a supporting medium (170).

In another aspect, the present invention further relates to a color conversion device (100) obtainable or obtained from the method of the present invention.

In another aspect, the present invention also relates to use of the color conversion device (100) of the present invention in an optical device (300) containing at least one functional medium (320, 420, 520) configured to modulate a light or configured to emit light.

In another aspect, the present invention furthermore relates to an optical device (300) containing at least one functional medium (320, 420, 520) configured to modulate a light or configured to emit light, and the color conversion device (100) of the present invention.

Further advantages of the present invention will become evident from the following detailed description.

### DESCRIPTION OF DRAWINGS

FIG. 1: shows a cross sectional view of a schematic of one embodiment of a color conversion film (100).

FIG. 2: shows a top view of a schematic of another embodiment of a color conversion film (100) of the invention.

FIG. 3: shows a cross sectional view of a schematic of one embodiment of an optical device (300) of the invention.

FIG. 4: shows a cross sectional view of a schematic of another embodiment of an optical device (300) of the invention.

FIG. 5: shows a cross sectional view of a schematic of another embodiment of an optical device (300) of the invention.

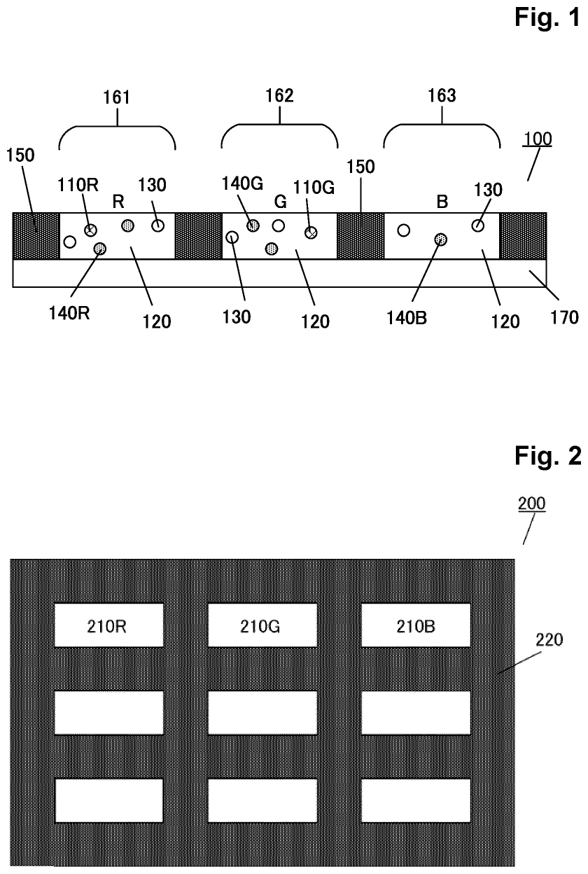

### LIST OF REFERENCE SIGNS IN FIG. 1

100. a color conversion device
110. a light emitting moiety
110R. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
161. a 1^{st} pixel
162. a 2^{nd} pixel
163. a 3^{rd} pixel
170. a supporting medium (a substrate) (optional)

### LIST OF REFERENCE SIGNS IN FIG. 2

200. a color conversion film
210R. a pixel (red)
210G. a pixel (green)
210B. a pixel (blue)
220. a bank

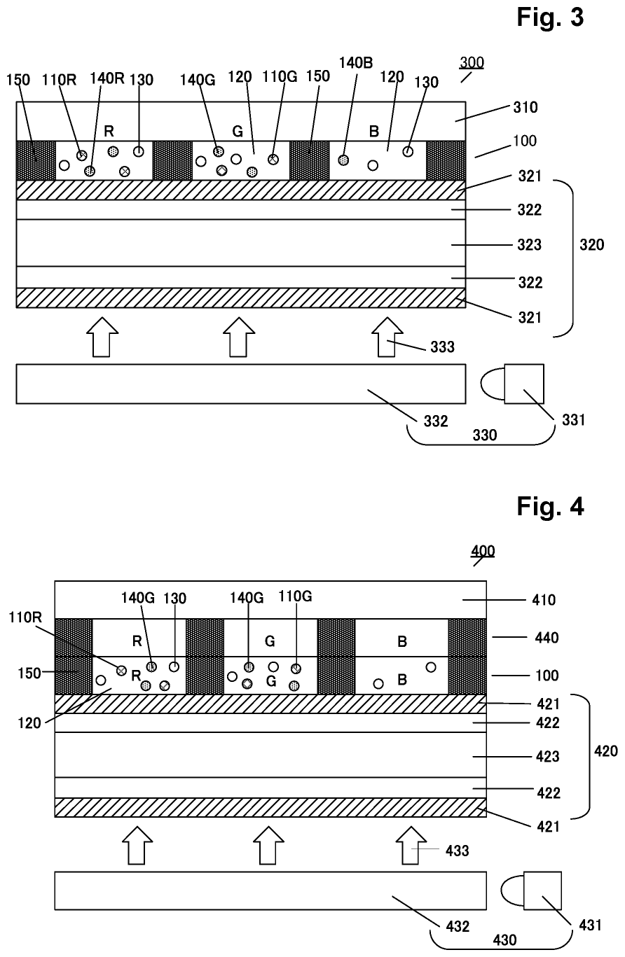

### LIST OF REFERENCE SIGNS IN FIG. 3

300. an optical device
100. a color conversion device
110. a light emitting moiety
110R. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
320. a light modulator
321. a polarizer
322. an electrode
323. a liquid crystal layer
330. a light source
331. a LED light source
332. a light guiding plate (optional)
333. light emission from the light source (330)

### LIST OF REFERENCE SIGNS IN FIG. 4

400. an optical device
100. a color conversion device
110. a light emitting moiety
110R. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
420. a light modulator
421. a polarizer
422. an electrode
423. a liquid crystal layer
430. a light source
431. a LED light source
432. a light guiding plate (optional)
440. a color filter
433. light emission from the light source (330)

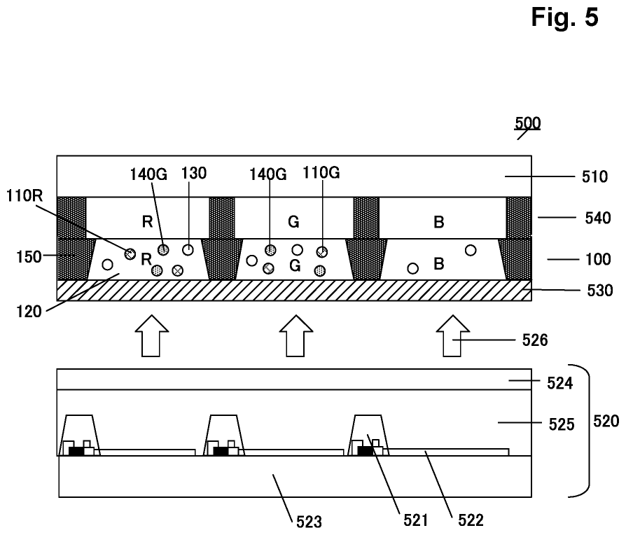

### LIST OF REFERENCE SIGNS IN FIG. 5

500. an optical device
100. a color conversion device
110. a light emitting moiety
110R. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
520. a light emitting device (e.g. OLED)
521. a TFT
522. an electrode (anode)
523. a substrate
524. an electrode (cathode)
525. light emitting layer (e.g. OLED layer(s))
526. light emission from a light emitting device (520)
530. an optical layer (e.g. polarizer) (optional)
540. a color filter

### Definition of the Terms

In the present specification, symbols, units, abbreviations, and terms have the following meanings unless otherwise specified.

In the present specification, unless otherwise specifically mentioned, the singular form includes the plural form and “one” or “that” means “at least one”. In the present specification, unless otherwise specifically mentioned, an element of a concept can be expressed by a plurality of species, and when the amount (for example, mass % or mol %) is described, it means sum of the plurality of species. “and/or” includes a combination of all elements and also includes single use of the element.

In the present specification, when a numerical range is indicated using “to” or “-”, it includes both endpoints and units thereof are common. For example, 5 to 25 mol % means 5 mol % or more and 25 mol % or less.

In the present specification, the hydrocarbon means one including carbon and hydrogen, and optionally including oxygen or nitrogen. The hydrocarbyl group means a monovalent or divalent or higher valent hydrocarbon. In the present specification, the aliphatic hydrocarbon means a linear, branched or cyclic aliphatic hydrocarbon, and the aliphatic hydrocarbon group means a monovalent or divalent or higher valent aliphatic hydrocarbon. The aromatic hydrocarbon means a hydrocarbon comprising an aromatic ring which may optionally not only comprise an aliphatic hydrocarbon group as a substituent but also be condensed with an alicycle. The aromatic hydrocarbon group means a monovalent or divalent or higher valent aromatic hydrocarbon. Further, the aromatic ring means a hydrocarbon comprising a conjugated unsaturated ring structure, and the alicycle means a hydrocarbon having a ring structure but comprising no conjugated unsaturated ring structure.

In the present specification, the alkyl means a group obtained by removing any one hydrogen from a linear or branched, saturated hydrocarbon and includes a linear alkyl and branched alkyl, and the cycloalkyl means a group obtained by removing one hydrogen from a saturated hydrocarbon comprising a cyclic structure and optionally includes a linear or branched alkyl in the cyclic structure as a side chain.

In the present specification, the aryl means a group obtained by removing any one hydrogen from an aromatic hydrocarbon. The alkylene means a group obtained by removing any two hydrogens from a linear or branched, saturated hydrocarbon. The arylene means a hydrocarbon group obtained by removing any two hydrogens from an aromatic hydrocarbon.

In the present specification, when polymer has a plural types of repeating units, these repeating units copolymerize. These copolymerization are any of alternating copolymerization, random copolymerization, block copolymerization, graft copolymerization, or a mixture of any of these.

According to the present invention, the term “(meth)acrylate polymer” means a methacrylate polymer, an acrylate polymer or a combination of methacrylate polymer and an acrylate polymer.

The term “emission” means the emission of electromagnetic waves by electron transitions in atoms and molecules.

In the present specification, Celsius is used as the temperature unit. For example, 20 degrees means 20 degrees Celsius.

### DETAILED DESCRIPTION OF THE INVENTION

According to the present invention, in one aspect, the composition comprises at least, essentially consisting of or consisting of;
i) a reactive monomer, preferably said monomer having one or more of functional groups, more preferably it is a(meth)acrylate monomer;
ii) a light emitting moiety; and
iii) a chemical compound comprising at least one group selected from unsaturated straight-chain alkyl group having carbon atoms 1 to 45; unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
preferably said group is selected from unsaturated straight-chain alkyl group having carbon atoms 1 to 45, unsaturated or saturated branched chain alkyl group having carbon atoms 3 to 45, straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
more preferably it is selected from unsaturated or saturated branched chain alkyl group having carbon atoms 3 to 45 or unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said carbon atoms of the alkyl group, the alkenyl group and/or the alkoxy group are in the range from 10 to 35, more preferably it is from 14 to 30,
furthermore preferably it is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said chain contains 1 to 5 carbon-carbon double bonds, more preferably 1 to 3 carbon-carbon double bonds, even more preferably 2 carbon-carbon double bonds,
wherein said chemical compound is not a polymer.

### —Chemical Compound

It is believed that the chemical compound is preferable to control viscosity/solubility of the composition accordingly. More preferably it can prevent increasement of viscosity of the composition and/or keeping a good solubility of the light luminescent moieties in a long term storage in the composition.

In a preferable embodiment of the present invention, said chemical compound further comprises at least one group selected from one or more of members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid, preferably said group is a phosphate group, a phosphonate group, thiol group, a carboxyl group or a combination of any of these, more preferably it is a carboxyl group.

It is believed that a phosphonate group, thiol group, a carboxyl group or a combination of any of these are more preferable since it has better attaching ability to the outer most surface of the inorganic part of the light emitting moiety (such as the surface of the inorganic part of quantum materials).

More preferably, the chemical compound is represented by following chemical formula (X^{A}).

Z(—X)u-Y (X^{A})
wherein
Z is *—R^{x1} or

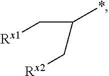

where “*” represents the connecting point to symbol Y of the formula, R^{x1} is a group selected from one or more members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid, preferably said group is a phosphonate group, thiol group, a carboxyl group or a combination of any of these, more preferably it is a carboxyl group; and
R² is a group selected from one or more of members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid, preferably said group is a phosphonate group, thiol group, a carboxyl group or a combination of any of these, more preferably it is a carboxyl group;
X is a single bond, an alkylene group having 1 to 15 carbon atoms, or an alkenylene group having 1 to 15 carbon atoms, or (poly)alkoxylene group having 1 to 15 carbon atoms, preferably Y is an (poly)alkoxylene group having 1 to 15 carbon atoms;
u is 0 or 1;
Y is selected from unsaturated straight-chain alkyl group having carbon atoms 1 to 45, unsaturated or saturated branched chain alkyl group having carbon atoms 3 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom; straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight chain aryl-alkyl group having carbon atoms 4 to 45, unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
preferably said group is selected from unsaturated straight-chain alkyl group having carbon atoms 1 to 45, unsaturated or saturated branched chain alkyl group having carbon atoms 3 to 45, straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
more preferably it is selected from unsaturated or saturated branched chain alkyl group having carbon atoms 3 to 45 or unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said carbon atoms of the alkyl group, the alkenyl group and/or the alkoxy group are in the range from 10 to 35, more preferably it is from 14 to 30,
furthermore preferably it is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said chain contains 1 to 5 carbon-carbon double bonds, more preferably 1 to 3 carbon-carbon double bonds, even more preferably 2 carbon-carbon double bonds,
said alkyl group, alkenyl group and/or alkoxy group, may optionally be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂, preferably Y is a straight-chain or branched alkyl group,
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another;

In case Y is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom, preferably u is 1 and Y is represented by the following formula,

*—[CH(R¹)—CH(R²)-Q]ₓ-R³,
wherein R¹ is H or an alkyl group having carbon atoms 1 to 5, preferably said alkyl group is an methyl group; R² is H or an alkyl group having carbon atoms 1 to 5, preferably said alkyl group is an methyl group, Q is an oxygen atom, nitrogen atom or sulfur atom, preferably Q is an oxygen atom; R³ is H or a methyl group, x is an integer, preferably x is in the range from 1 to 300, more preferably from 2 to 200, even more preferably from 4 to 100, where “*” represents the connecting point to symbol X of the formula;
or

*—[(CHR¹)ₙ-Q)]ₓ-R³
wherein n is 2 or 3, Q is an oxygen atom, nitrogen atom or sulfur atom, preferably Q is an oxygen atom, R¹ is H or a methyl group, R³ is H or a methyl group, n is 1 to 5, preferably 1 to 3, more preferably n is 2, x is an integer, preferably x is in the range from 1 to 300, more preferably from 2 to 200, even more preferably from 4 to 100, where “*” represents the connecting point to symbol X of the formula,
and
preferably wherein Z represents an attaching group comprising one or two
S atoms or Z is a carboxyl group, preferably Z is

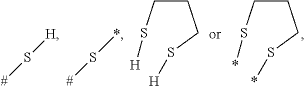

more preferably

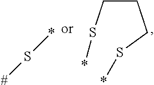

where “#” represents the connecting point to group X, and “*” represents the connecting point to the surface of the light emitting moiety.

It is believed that said weight ratio of the chemical compound is very preferable to control viscosity/solubility of the composition accordingly. And it is very preferable to prevent increasement of viscosity of the composition and/or keeping a good solubility of the light luminescent moieties in a long term storage in the composition.

### —Reactive Monomer

It is believed that the lower viscosity is important to make a low viscosity composition suitable for inkjet printing. Therefore, a (meth)acrylate monomer having the viscosity value within the above-mentioned parameter ranges are especially suitable to make a composition for inkjet printing. By using these (meth)acrylate monomer in a composition, when it is mixed with another material such as semiconducting light emitting nanoparticles with high loading, the composition can still keep lower viscosity within the range suitable for inkjet printing.

In a preferred embodiment of the present invention, the boiling point (B.P.) of said reactive monomer is 250° C. or more, preferably it is in the range from 250° C. to 350° C., even more preferably from 280° C. to 350° C., further more preferably from 300° C. to 348° C. for large area uniform inkjet printing.

It is believed that said high boiling point is also important to make a composition having a lower vapor pressure preferably less than 0.001 mmHg for large area uniform printing, it is preferable to use a reactive monomer, preferably a (meth)acrylate monomer, more preferably a (meth)acrylate monomer of formula (I), (II) and/or (III) having the viscosity value of 25 cP or less at 25° C. and the boiling point at least 250° C. or more, preferably it is in the range from 250° C. to 350° C., more preferably from 300° C. to 348° C. to make a composition suitable for large area uniform inkjet printing even if it is mixed with high loading of another materials such as high loading of semiconducting light emitting nanoparticles.

Here, the term “(meth)acrylate” is a general term for an acrylate and a methacrylate. Therefore, according to the present invention, the term “(meth)acrylate monomer” means a methacrylate monomer and or a acrylate monomer.

According to the present invention, said B.P can be estimate by the known method such as like described in Science of Petroleum, Vol. II. p. 1281 (1398).

According to the present invention, any types of publicly available acrylates and/or methacrylates represented by chemical formula (I) or (II) can be used preferably.

Especially for the first aspect, any types of publicly available acrylates and/or methacrylates having the viscosity value of 25 cP or less at 25° C. represented by chemical formula (I), (II) and/or (III) can be used.

Thus, according to the present invention, the reactive monomer of the composition is preferably a (meth)acrylate monomer selected from a mono-(meth)acrylate monomer, a di-(meth)acrylate monomer or a tri-(meth)acrylate monomer more preferably it is represented by following chemical formula (II);

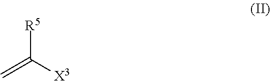

X³ is a non-substituted or substituted alkyl group, aryl group or an alkoxy group;
preferably the symbol X³ is

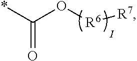

where “*” on the left side of the formula represents the connecting point to the end group C═CR⁵ of the formula (I);
I is 0 or 1;
R⁵ is a hydrogen atom, halogen atom of Cl, Br, or F, methyl group, alkyl group, aryl group, alkoxy group, ester group, or a carboxylic acid group;
R⁶ is a straight alkylene chain or alkoxylene chain having 1 to 25 carbon atoms, preferably R⁶ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R⁷ is a straight alkylene chain or alkoxylene chain having 1 to 25 carbon atoms, preferably R⁷ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R⁸ is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another.

In a preferable embodiment, the composition further comprises a (meth)acrylate monomer represented by following chemical formula (I) and/or a (meth)acrylate monomer represented by following chemical formula (III);

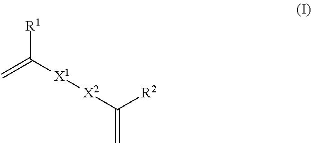

wherein
X¹ is a non-substituted or substituted alkyl group, aryl group or an alkoxy group or an ester group;
X² is a non-substituted or substituted alkyl group, aryl group or an alkoxy group or an ester group;
R¹ is a hydrogen atom, halogen atom of Cl, Br, or F, methyl group, alkyl group, aryl group, alkoxy group, ester group, or a carboxylic acid group;
R² is a hydrogen atom, halogen atom of Cl, Br, or F, methyl group, alkyl group, aryl group, alkoxy group, ester group, or a carboxylic acid group;
preferably the symbol X¹ is

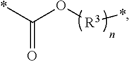

where “*” on the left side of the formula represents the connecting point to the carbon atom of the end group C═CR¹ of the formula (I) and “*” on the right side represents the connecting point to symbol X² of the formula (I);
n is 0 or 1;
preferably the symbol X² is

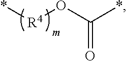

where “*” on the left side of the formula represents the connecting point to symbol X1 of the formula (I) and “*” on the right side represents the connecting point to the end group C═CR² of the formula (I);
m is 0 or 1;
preferably at least m or n is 1;
R³ is a straight alkylene chain or alkoxylene chain having 1 to 25 carbon atoms, a cycloalkane having 3 to 25 carbon atoms or an aryl group having 3 to 25 carbon atoms, preferably R³ is a straight alkylene chain or alkoxylene chain having 1 to 15 carbon atoms, more preferably 1 to 5 carbon atoms,
which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R⁴ is a straight alkylene chain or alkoxylene chain having 1 to 25 carbon atoms, a cycloalkane having 3 to 25 carbon atoms or an aryl group having 3 to 25 carbon atoms, preferably R⁴ is a straight alkylene chain or alkoxylene chain having 1 to 15 carbon atoms, more preferably 1 to 5 carbon atoms,
which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another;

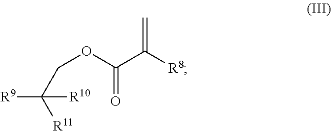

wherein R⁹ is hydrogen atom, a straight alkyl group having 1 to 25 carbon atoms or a (meth)acryl group represented by chemical formula (IV)

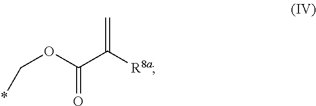

R¹⁰ is hydrogen atom, a straight alkyl group having 1 to 25 carbon atoms or a (meth)acryl group represented by chemical formula (V)

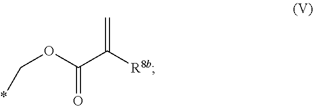

R¹¹ is hydrogen atom, a straight alkyl group having 1 to 25 carbon atoms or a (meth)acryl group represented by chemical formula (VI)

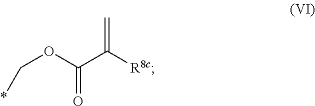

wherein R^{8a}, R^{8b} and R^{8c} are, each independently or dependently of each other at each occurrence, H or CH₃;
wherein at least one of R⁹, R¹⁰ and R¹¹ is a (meth)acryl group, preferably two of R⁹, R¹⁰ and R¹¹ are a (meth)acryl group and other one is a hydrogen atom or a straight alkyl group having 1 to 25 carbon atoms, preferably the electric conductivity (S/cm) of the (meth)acrylate monomer of formula (III) is 1.0*10⁻¹⁰ or less, preferably it is 5.0*10⁻¹¹ or less, more preferably it is in the range from 5.0*10⁻¹¹ to 1.0*10⁻¹⁵, even more preferably it is in the range from 5.0*10⁻¹² to 1.0*10⁻¹⁵.

In a preferred embodiment of the present invention, the (meth)acrylate monomer of chemical formula (II) is in the composition and the mixing ratio of the (meth)acrylate monomer of chemical formula (I) to the (meth)acrylate monomer of chemical formula (II) is in the range from 1:99 to 99:1 (formula (I): formula (II)), preferably from 5:95 to 50:50, more preferably from 10:90 to 40:60, even more preferably it is from 15:85 to 35:65, preferably at least a purified (meth)acrylate monomer represented by chemical formula (I), (II) is used in the composition, more preferably the (meth)acrylate monomer of chemical formula (I) and the (meth)acrylate monomer of chemical formula (II) are both obtained or obtainable by a purification method.

In a preferred embodiment, the boiling point (B.P.) of said (meth)acrylate monomer of chemical formula (I) and/or chemical formula (II) is 250° C. or more, preferably the (meth)acrylate monomers of chemical formula (I) and chemical formula (II) are both 250° C. or more, more preferably it is in the range from 250° C. to 350° C., even more preferably from 280° C. to 350° C., further more preferably from 300° C. to 348° C.

In a preferred embodiment of the present invention, the viscosity of the composition is 35 cP or less at room temperature, preferably in the range from 1 to 35 cP, more preferably from 2 to 30 cP, even more preferably from 2 to 25 cP.

According to the present invention, said viscosity can be measured by vibration type viscometer VM-10A (SEKONIC) at room temperature. https://www.sekonic.co.jplenglish/product/viscometer/vm/vm_series.html

### —(Meth)Acrylate Monomer Represented by Chemical Formula (I) as a Matrix Material

Furthermore preferably, said R³ of formula (I) and R⁴ of formula (I) are, each independently of each other, selected from the following groups, wherein the groups can be substituted with R^{a}, preferably they are unsubstituted by R^{a}.

*—(CH₂)₁—*
*—(CH₂)₂—*
*—(CH₂)₃—*
*—(CH₂)₄—*
*—(CH₂)₅—*
*—(CH₂)₆—*
*—(CH₂)₇—*

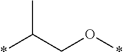 [SMILES: *OCC(*)C]

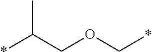 [SMILES: *COCC(*)C]

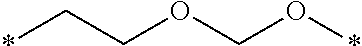 [SMILES: *CCOCO*]

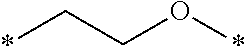 [SMILES: *CCO*]

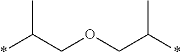 [SMILES: *C(C)COCC(*)C]

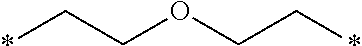 [SMILES: *CCOCC*]

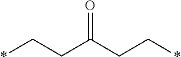 [SMILES: *CCC(=O)CC*]

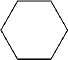

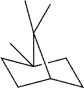

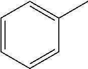

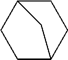

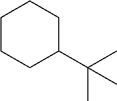

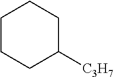

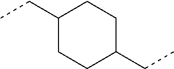

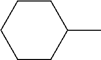

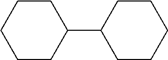 [SMILES: C1CCC(C2CCCCC2)CC1]

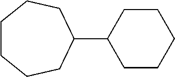 [SMILES: C1CCCC(C2CCCCC2)CC1]

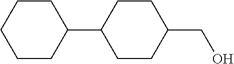 [SMILES: OCC1CCC(C2CCCCC2)CC1]

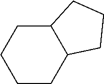

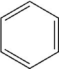

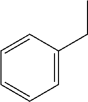

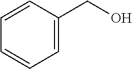

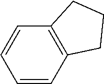

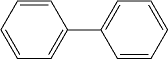 [SMILES: c1ccc(-c2ccccc2)cc1]

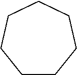

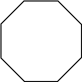

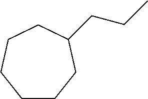

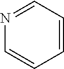

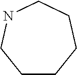

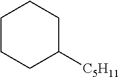

Particularly preferably, said R³ and R⁴ of formula (I) are, at each occurrence, independently or differently, selected from the following groups.

*—(CH₂)₁—*
*—(CH₂)₂—*
*—(CH₂)₃—*
*—(CH₂)₄—*
*—(CH₂)₅—*
*—(CH₂)₆—*
*—(CH₂)₇—*

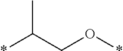 [SMILES: *OCC(*)C]

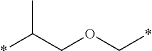 [SMILES: *COCC(*)C]

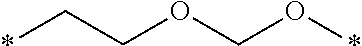 [SMILES: *CCOCO*]

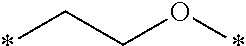 [SMILES: *CCO*]

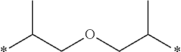 [SMILES: *C(C)COCC(*)C]

wherein “*” represents the connecting point to oxygen atom of the formula or the connecting point to X² of the formula in case of R³, and wherein “*” represents the connecting point to oxygen atom of the formula or the connecting point to X¹ of the formula in case of R⁴.

Furthermore preferably, said formula (I) is NDDA (nonanediol diacrylate; BP:342° C.), HDDMA (hexanediol dimethacrylate; BP:307), HDDA (hexanediol diacrylate; BP:295° C.) or DPGDA (BP: 314° C.).

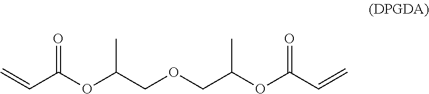 [SMILES: C=CC(=O)OC(C)COCC(C)OC(=O)C=C]

### —(Meth)Acrylate Monomer Represented by Chemical Formula (II)

It is believed that the (meth)acrylate monomer represented by following chemical formula (II) shows much lower viscosity value than the viscosity of the (meth)acrylate monomer of formula (I). Thus, by using the (meth)acrylate monomer represented by chemical formula (II) in combination of the (meth)acrylate monomer of chemical formula (I), a composition having much lower viscosity desirable for smooth inkjet printing can be realized, preferably without decreasing External Quantum Efficiency (EQE) value.

It is believed that said combination can realize a low viscosity composition comprising high amount of another materials, such as high loading of semiconducting light emitting nanoparticles. Thus, it is especially suitable for an inkjet printing when the composition comprises another material.

In a preferable embodiment of the present invention, the boiling point (B.P.) of said (meth)acrylate monomer of chemical formula (II) is 250° C. or more, preferably the (meth)acrylate monomer of chemical formula (II) is 250° C. or more, more preferably it is in the range from 250° C. to 350° C., even more preferably from 280° C. to 350° C., further more preferably from 300° C. to 348° C. for large area uniform inkjet printing.

In a further preferable embodiment of the present invention, the boiling point (B.P.) of said (meth)acrylate monomer of chemical formula (I) and/or the boiling point (B.P.) of said (meth)acrylate monomer of chemical formula (II) is 250° C. or more, preferably the (meth)acrylate monomers of chemical formula (I) and chemical formula (II) are both 250° C. or more, more preferably it is in the range from 250° C. to 350° C., even more preferably from 280° C. to 350° C., further more preferably from 300° C. to 348° C. for large area uniform inkjet printing.

Furthermore preferably, said R⁷ of formula (II) is, at each occurrence, independently or differently, selected from the following groups, wherein the groups can be substituted with R^{a}, preferably they are unsubstituted by R^{a}.

| | | |
|---|---|---|
| *—(CH₂)₆—CH₃ | *—(CH₂)₇—CH₃ | *—(CH₂)₈—CH₃ |
| *—(CH₂)₉—CH₃ | *—(CH₂)₁₀—CH₃ | *—(CH₂)₁₁—CH₃ |
| *—(CH₂)₁₂—CH₃ | *—(CH₂)₄—OH | *—(CH₂)₂—OH |
| *—(CH₂)₆—OH | *—(CH₂)₃—OH | *—(CH₂)₅—OH |

wherein “*” represents the connecting point to R⁶ of X³ in case I is 1, and it is representing the connecting point to oxygen atom of X³ of the formula (II) in case n is 0.

The furthermore preferably, said formula (II) is Lauryl methacrylate (LM, viscosity 6 cP, BP: 142° C.) or Lauryl acrylate (LA, viscosity: 4.0 cP, BP: 313.2° C.).

It is believed that the higher amount of the (meth)acrylate monomer of chemical formula (II) to the total amount of the (meth)acrylate monomer of chemical formula (I) leads improved EQE of the composition, and the mixing weight ratio of the (meth)acrylate monomer of chemical formula (II) to the total amount of the (meth)acrylate monomer of chemical formula (I) less than 50 wt. % is preferable from the view point of viscosity of the composition, better ink-jetting properties of the composition.

Preferably, (meth)acrylate monomers purified by using silica column are used.

It is believed that an impurity removal from the (meth)acrylate monomers by the silica column purification leads improved QY of the semiconducting light emitting nanoparticle in the composition.

### —(Meth)Acrylate Monomer of Chemical Formula (III)

It is believed that the (meth)acrylate monomer of chemical formula (III) is useful to improve its solidity of a later made from the composition after inkjet printing.

According to the present invention, a publicly known a (meth)acrylate monomer represented by following chemical formula (III) can be used to improve solidity of a layer after inkjet printing and cross linking.

Very preferably, Trimethylolpropane Triacrylate (TMPTA) is used as the (meth)acrylate monomer of chemical formula (III).

In a preferable embodiment of the present invention, the amount of the (meth)acrylate monomer of chemical formula (III) based on the total amount of (meth)acrylate monomers in the composition is in the range from 0.001 wt. % to 25 wt. %, more preferably in the range from 0.1 wt. % to 15 wt. %, even more preferably from 1 wt. % to 10 wt. %, further more preferably from 3 to 7 wt %.

Preferably, there (meth)acrylate monomers are purified by using silica column, are used.

It is believed that an impurity removal from the (meth)acrylate monomers by the silica column purification leads improved QY of the semiconducting light emitting nanoparticle in the composition.

According to the present invention, preferably the composition is configured to show the EQE value 23% or more, preferably 24% or more and less than 95, preferably less than 50%.

According to the present invention, said EQE is measured by the following EQE measurement process at room temperature which is based on using an integrating sphere, equipped with a 450 nm excitation light source coupled in via an optical fiber, and a spectrometer (Compass X, BWTEK), and which consists of a first measurement using air as the reference to detect the incident photons of the excitation light and a second measurement with the sample or test cell placed in front of the integrating sphere in between the opening of the integrating sphere and the exit of the optical fiber to detect the photons incident from the excitation light source transmitted through the sample and the photos emitted from the sample or test cell, whereas for both cases photons exiting the integrating sphere are counted by the spectrometer and EQE and BL calculation is done with the following equations and the number of photons of the excitation light and emission light is calculated by integration over the following wavelength ranges;
EQE=Photons [Emission light]/Photons [Excitation light measured without sample in place];
BL=Photons [Excitation light measured with sample in place]/Photons [Excitation light measured without sample in place];
Emission light if green light emitting moieties are used: 490 nm-600 nm,
Emission light if red light emitting moieties are used: 560 nm-780 nm
Excitation light: 390 nm-490 nm.

According to the present invention, in a preferred embodiment, the viscosity of the composition is 35 cP or less at room temperature, preferably in the range from 1 to 35 cP, more preferably from 2 to 30 cP, even more preferably from 2 to 25 cP.

In a preferred embodiment of the present invention, the composition comprises a solvent 10 wt % or less based on the total amount of the composition, more preferably it is 5 wt % or less, more preferably it is a solvent free composition, preferably the composition does not comprise any one of the following solvent selected from one or more members of the group consisting of ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; propylene glycol monoalkyl ethers, such as, propylene glycol monomethyl ether (PGME), propylene glycol monoethyl ether, and propylene glycol monopropyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, triethylene glycol and glycerin; esters, such as, ethyl 3-ethoxypropionate, methyl 3-methoxypropionate and ethyl lactate; and cyclic asters, such as, gamma-butyro-lactone; chlorinated hydrocarbons, such as chloroform, dichloromethane, chlorobenzene, trimethyl benzenes such as 1,3,5-trimethylbenzene, 1,2,4-trimethyl benzene, 1,2,3-trimethyl benzene, docecylbenzene, cyclohexylbenzene, 1,2,3,4-tetramethylbenzene, 1,2,3,5-tetramethylbenzene, 3-isopropylbiphenyl, 3-methylbiphenyl, 4-methylbiphenyl and dichlorobenzene, preferably said solvent is propylene glycol alkyl ether acetates, alkyl acetates, ethylene glycol monoalkyl ethers, propylene glycol, and propylene glycol monoalkyl ethers.

It is believed that the less than 10 wt % of solvent in the composition leads improved ink-jetting and it can avoid 2^{nd} or more ink-jetting onto the same pixel after evaporation of the solvent.

According to the present invention, it is desirable not to add any solvent to realize large area inkjet printing with improved uniformity without causing any clogging at a nozzle and/or with good dispersity of semiconducting light emitting nanoparticles and/or with good dispersity of scattering particles.

According to the present invention, preferably the composition further comprises an another material selected from one or more members of the group consisting of;
iii) another light emitting moiety which is different from the light emitting moiety of claim 1, preferably said light emitting moiety comprises a ligand, more preferably said light emitting moiety comprises an alkyl type ligand having carbon atoms 2 to 25;
iv) another (meth)acrylate monomer;
v) scattering particles, and
vi) optically transparent polymers, anti-oxidants, radical quenchers, photo initiators and/or surfactants.

In some embodiments of the present invention, preferably the composition of the present invention comprises
v) scattering particles; and
vii) at least one polymer configured so that said polymer enables to the scattering particles to disperse in the composition;
wherein the polymer comprises at least a phosphine group, phosphine oxide group, phosphate group, phosphonate group, thiol group, tertiary amine, carboxyl group, hetero cyclic group, silane group, sulfonic acid, hydroxyl group, phosphonic acid, or a combination of thereof, preferably the polymer comprises a tertiary amine, phosphine oxide group, phosphonic acid, or a phosphate group.

According to the present invention, the polymer configured so that said polymer enables to the scattering particles to disperse in the composition comprises at least a repeating unit A comprising a phosphine group, phosphine oxide group, phosphate group, phosphonate group, thiol group, tertiary amine, carboxyl group, hetero cyclic group, silane group, sulfonic acid, hydroxyl group, phosphonic acid, or a combination of thereof, preferably the repeating unit A comprises a tertiary amine, phosphine oxide group, phosphonic acid, or a phosphate group.

In some embodiments of the present invention, the repeating unit A and the repeating unit B are a constitutional repeating unit.

Even more preferably, the repeating unit A comprises a tertiary amine represented by following chemical formula (VII),

NR¹²R¹³R¹⁴— (VII)
wherein R¹² is a hydrogen atom, a straight or a branched alkyl group having 1 to 30 carbon atoms, or an aryl group having 1 to 30 carbon atoms; R¹³ is a hydrogen atom, a straight or a branched alkyl group having 1 to 30 carbon atoms, or an aryl group having 1 to 30 carbon atoms; R¹² and R¹³ can be same or different of each other; R¹⁴ is a single bond, a straight or a branched alkylene group having 1 to 30 carbon atoms, alkenylene group having 1 to 30 carbon atoms, (poly)oxaalkylene group having 1 to 30 carbon atoms.

Even more preferably, R¹² is a straight or a branched alkyl group having 1 to 30 carbon atoms; R¹³ is a straight or a branched alkyl group having 1 to 30 carbon atoms; R¹² and R¹³ can be same or different of each other. Furthermore preferably, R¹² is methyl group, ethyl group, n-propyl group, or n-butyl group; R¹³ is methyl group, ethyl group, n-propyl group, or n-butyl group.

According to the present invention, in a preferred embodiment, the repeating unit A does not contain a salt.

In a preferred embodiment of the present invention, the polymer is a copolymer selected from the group consisting of graft copolymers, block copolymers, alternating copolymers, and random copolymers, preferably said copolymer comprises the repeating unit A, and repeating unit B that does not include any phosphine group, phosphine oxide group, phosphate group, phosphonate group, thiol group, tertiary amine, carboxyl group, hetero cyclic group, silane group, sulfonic acid, hydroxyl group, phosphonic acid, and a combination of thereof, more preferably the copolymer is a block copolymer represented by following chemical formula (VII) or (IX),

Aₙ-Bₘ (VIII)

Bₒ-Aₙ-Bₘ (IX)
wherein the symbol “A” represents a repeating unit A; the symbol “B” is taken to mean the repeating unit B; the symbols “n”, “m”, and “o” are at each occurrence, independently or dependently of each other, integers 1 to 100, preferably 5 to 75, more preferably 7 to 50; even more preferably the repeating unit B comprises a polymer chain selected from the group consisting of (poly)ethylene, (poly)phenylene, polydivinylbenzene, (poly)ethers, (poly)esters, (poly)amides, (poly)urethanes, (poly)carbonates, polylactic acids, (poly)vinyl esters, (poly)vinyl ethers, polyvinyl alcohols, polyvinylpyrrolidones, celluloses and derivatives of any of these.

In a preferred embodiment of the present invention, the polymer chain of the repeating unit B is a polyethylene glycol.

More preferably, the repeating unit B comprises a chemical structure represented by following chemical formula (X),

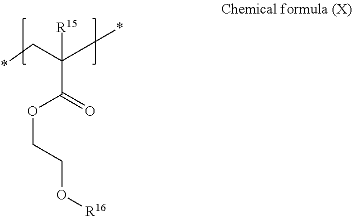

wherein the chemical formula (X), R¹⁵ is hydrogen atom, or methyl group; R¹⁶ is alkyl group having 1 to 10 carbon atoms; and n is an integer 1 to 5, “*” represents the connecting point to an another polymer repeating unit or a terminal of the polymer.

Even more preferably, R¹⁵ can be a hydrogen atom, or methyl group, R¹⁶ can be an ethyl group, and n is an integer 1 to 5.

In some embodiments of the present invention, the surface of the core, or the outermost surface of one or more shell layers of the semiconducting light emitting nanoparticle can be partly or fully over coated by the polymer. By using ligand exchange method, described in for example, Thomas Nann, Chem. Commun., 2005, 1735-1736, DOI: 10.1039/b-414807j, the polymer can be introduced onto the surface of the core or the outermost surface of the core of the semiconducting light emitting nanoparticle.

According to the present invention, in some embodiments, the content of said polymer is in the range from 1% to 500% by weight, more preferably in the range from 20% to 350% by weight, even more preferably from 50% to 200% by weight with respect to the total weight of the semiconducting light emitting nanoparticle.

In a preferred embodiment of the present invention, the weight average molecular weight (Mw) of the polymer is in the range from 200 g/mol to 30,000 g/mol, preferably from 250 g/mol to 5,000 g/mol, more preferably from 300 g/mol to 2,000 g/mol.

The molecular weight M_{w} is determined by means of GPC (=gel permeation chromatography) against an internal polystyrene standard.

As the polymer, commercially available wetting and dispersing additives which can be solved in non-polar and/or low polar organic solvent can be used preferably. Such as BYK-111, BYK-LPN6919, BYK-103, BYK-P104, BYK-163 ([trademark], from BYK com.), TERPLUS MD1000 series, such as MD1000, MD1100 ([trademark], from Otsuka Chemical), Poly(ethylene glycol) methyl ether amine (Sigma-Ald 767565 [trademark], from Sigma Aldrich), Polyester bis-MPA dendron, 32 hydroxyl, 1 thiol, (Sigma-Ald 767115 [trademark], from Sigma Aldrich), LIPONOL DA-T/25 (From Lion Specialty Chemicals Co.), Carboxymethyl cellulose (from Polyscience etc.), another wetting and dispersing additives disclosed in for examples, “Marc Thiry et. al., ACSNANO, American Chemical society, Vol. 5, No. 6, pp 4965-4973, 2011”, “Kimihiro Susumu, et. al., J. Am. Chem. Soc. 2011, 133, pp 9480-9496”.

Thus, in some embodiments of the present invention, the composition comprises at least the (meth)acrylate monomer of chemical formula (I), the (meth)acrylate monomer of chemical formula (II) and the polymer configured so that said polymer enables to the scattering particles to disperse in the composition, wherein the mixing ratio of the (meth)acrylate monomer of chemical formula (I): the (meth)acrylate monomer of chemical formula (II): the polymer is 10:89:1 to 50:40:10, preferably in the range from 15:82:3 to 30:60:10.

In some embodiments of the present invention, the composition comprises at least the (meth)acrylate monomer of chemical formula (III), the (meth)acrylate monomer of chemical formula (II) and the polymer configured so that said polymer enables to the scattering particles to disperse in the composition, wherein the mixing ratio of the (meth)acrylate monomer of chemical formula (III): the (meth)acrylate monomer of chemical formula (II): the polymer is 10:89:1 to 50:40:10, preferably in the range from 15:82:3 to 30:60:10.

In some embodiment of the present invention, a composition comprises, essentially consisting of or consisting of, at least a polymer derived or derivable from the (meth)acrylate monomers of the composition of the present invention.

In a preferred embodiment of the present invention, said polymer is derived or derivable from all the (meth)acrylate monomers in the composition, for example, at least the (meth)acrylate monomer of chemical formula (I) and/or the (meth)acrylate monomer of chemical formula (II).

### v) Scattering Particles

According to the present invention, as the scattering particles, publicly known small particles of inorganic oxides such as SiO₂, SnO₂, CuO, CoO, Al₂O₃TiO₂, Fe₂O₃, Y₂O₃, ZnO, ZnS, MgO; organic particles such as polymerized polystyrene, polymerized PMMA; inorganic hollow oxides such as hollow silica or a combination of any of these; can be used. The amount of the scattering particles is preferably 8 wt % or less based on the total amount of the solid contents of the layer, preferably it is in the range from 4 to 0 wt %, more preferably it is in the range from 1 to 0 wt %, more preferably the layer and/or the composition does not contain any scattering particles.

In some embodiments of the present invention, the composition comprises iii) at least one semiconducting light emitting nanoparticle comprising a 1^{st} semiconducting nanoparticle, optionally one or more shell layers covering at least a part of the 1^{st} semiconducting nanoparticle, preferably the composition has EQE value 23% or more, preferably 24% or more and less than 95%, preferably less than 50%.

According to the present invention, as a transparent polymer, a wide variety of publicly known transparent polymers suitable for optical devices, described in for example, WO 2016/134820A can be used preferably.

According to the present invention, the term “transparent” means at least around 60% of incident light transmit at the thickness used in an optical medium and at a wavelength or a range of wavelength used during operation of an optical medium. Preferably, it is over 70%, more preferably, over 75%, the most preferably, it is over 80%.

According to the present invention the term “polymer” means a material having a repeating unit and having the weight average molecular weight (Mw) 1000 g/mol, or more.

The molecular weight M_{w} is determined by means of GPC (=gel permeation chromatography) against an internal polystyrene standard.

In some embodiments of the present invention, the glass transition temperature (Tg) of the transparent polymer is 70° C. or more and 250° C. or less.

Tg is measured based on changes in the heat capacity observed in Differential scanning colorimetry like described in Rickey J Seyler, Assignment of the Glass Transition, ASTM publication code number (PCN) 04-012490-50.

For example, as the transparent polymer for the transparent matrix material, poly(meth)acrylates, epoxys, polyurethanes, polysiloxanes, can be used preferably.

In a preferred embodiment of the present invention, the weight average molecular weight (Mw) of the polymer as the transparent matrix material is in the range from 1,000 to 300,000 g/mol, more preferably it is from 10,000 to 250,000 g/mol.

According to the present invention, publicly known anti-oxidants, radical quenchers, photo initiators and/or surfactants can be used preferably like described in WO 2016/134820A.

### —Light Emitting Moiety (110)

In a preferable embodiment of the present invention, said light emitting moiety (110) is an organic and/or inorganic light emitting material, preferably it is an organic dye, inorganic phosphor and/or a semiconducting light emitting nanoparticle such as a quantum material.

In some embodiments of the present invention, the total amount of the light emitting moiety (110) is in the range from 0.1 wt. % to 90 wt. % based on the total amount of the 1^{st} pixel (161), preferably from 10 wt. % to 70 wt. %, more preferably from 30 wt. % to 50 wt. %.

—iii) Semiconducting Light Emitting Nanoparticle

According to the present invention, the term “semiconductor” means a material that has electrical conductivity to a degree between that of a conductor (such as copper) and that of an insulator (such as glass) at room temperature. Preferably, a semiconductor is a material whose electrical conductivity increases with the temperature.

The term “nanosized” means the size in between 0.1 nm to 150 nm, more preferably 3 nm to 50 nm.

Thus, according to the present invention, “semiconducting light emitting nanoparticle” is taken to mean that the light emitting material which size is in between 0.1 nm to 150 nm, more preferably 3 nm to 50 nm, having electrical conductivity to a degree between that of a conductor (such as copper) and that of an insulator (such as glass) at room temperature, preferably, a semiconductor is a material whose electrical conductivity increases with the temperature, and the size is in between 0.1 nm and 150 nm, preferably 0.5 nm to 150 nm, more preferably 1 nm to 50 nm.

According to the present invention, the term “size” means the average diameter of circle with an area equal to an average area of dark contrast features in TEM image.

The average diameter of the semiconducting nanosized light emitting particles is calculated based on 100 semiconducting light emitting nanoparticles in a TEM image created by a Tecnai G2 Spirit Twin T-12 Transmission Electron Microscope.

In a preferred embodiment of the present invention, the semiconducting light emitting nanoparticle of the present invention is a quantum sized material.

According to the present invention, the term “quantum sized” means the size of the semiconducting material itself without ligands or another surface modification, which can show the quantum confinement effect, like described in, for example, ISBN:978-3-662-44822-9.

For example, CdS, CdSe, CdTe, ZnS, ZnSe, ZnSeS, ZnTe, ZnO, GaAs, GaP, GaSb, HgS, HgSe, HgSe, HgTe, InAs, InP, InPZn, InPZnS, InPZnSe, InPZnSeS, InPZnGa, InPGaS, InPGaSe, InPGaSeS, InPZnGaSeS and InPGa, InCdP, InPCdS, InPCdSe, InSb, AlAs, AIP, AISb, Cu₂S, Cu₂Se, CuInS2, CuInSe2, Cu₂(ZnSn)S₄, Cu₂(InGa)S₄, TiO₂ alloys and a combination of any of these can be used.

In a preferred embodiment of the present invention, the 1^{st} semiconducting material comprises at least one element of the group 13 of the periodic table, and one element of the group 15 of the periodic table, preferably the element of the group 13 is In, and the element of the group 15 is P, more preferably the 1^{st} semiconducting material is selected from the group consisting of InP, InPZn, InPZnS, InPZnSe, InPZnSeS, InPZnGa, InPGaS, InPGaSe, InPGaSeS, InPZnGaSeS and InPGa.

According to the present invention, a type of shape of the core of the semiconducting light emitting nanoparticle, and shape of the semiconducting light emitting nanoparticle to be synthesized are not particularly limited.

For examples, spherical shaped, elongated shaped, star shaped, polyhedron shaped, pyramidal shaped, tetrapod shaped, tetrahedron shaped, platelet shaped, cone shaped, and irregular shaped core and-or a semiconducting light emitting nanoparticle can be synthesized.

In some embodiments of the present invention, the average diameter of the core is in the range from 1.5 nm to 3.5 nm.

The average diameter of the core is calculated based on 100 semiconducting light emitting nanoparticles in a TEM image created by a Tecnai G2 Spirit Twin T-12 Transmission Electron Microscope by measuring the longest axis of each single particles.

In some embodiments of the present invention, at least one the shell layer comprises or a consisting of a 1^{st} element of group 12 of the periodic table and a 2^{nd} element of group 16 of the periodic table, preferably, the 1^{st} element is Zn, and the 2^{nd} element is S, Se, or Te; preferably a first shell layer covering directly onto said core comprises or a consisting of a 1^{st} element of group 12 of the periodic table and a 2^{nd} element of group 16 of the periodic table, preferably, the 1^{st} element is Zn, and the 2^{nd} element is S, Se, or Te.

In a preferred embodiment of the present invention, at least one shell layer (a first shell layer) is represented by following formula (XI), preferably the shell layer directly covering the core is represented by the chemical formula (XI);

ZnSₓSe_{y}Te_{z} (XI)
wherein 0≤x≤1, 0≤y≤1, 0≤z≤1, and x+y+z=1, preferably 0≤x≤1, 0≤y≤1, z=0, and x+y=1, preferably, the shell layer is ZnSe, ZnS, ZnSₓSe_{y}, ZnSe_{y}Te_{z} or ZnSₓTe_{z}.

In some embodiments of the present invention, said shell layer is an alloyed shell layer or a graded shell layer, preferably said graded shell layer is ZnSₓSe_{y}, ZnSe_{y}Te_{z}, or ZnSₓTe_{z}, more preferably it is ZnSₓSe_{y}.

In some embodiments of the present invention, the semiconducting light emitting nanoparticle further comprises 2^{nd} shell layer onto said shell layer, preferably the 2^{nd} shell layer comprises or a consisting of a 3^{rd} element of group 12 of the periodic table and a 4^{th} element of group 16 of the periodic table, more preferably the 3^{rd} element is Zn, and the 4^{th} element is S, Se, or Te with the proviso that the 4^{th} element and the 2^{nd} element are not same.

In a preferred embodiment of the present invention, the 2^{nd} shell layer is represented by following formula (XI′),

ZnSₓSe_{y}Te_{z} (XI′)
wherein 0≤x≤1, 0≤y≤1, 0≤z≤1, and x+y+z=1, preferably, the shell layer is ZnSe, ZnSₓSe_{y}, ZnSe_{y}Te_{z}, or ZnSₓTe_{z} with the proviso that the shell layer and the 2^{nd} shell layer is not the same.

In some embodiments of the present invention, said 2^{nd} shell layer can be an alloyed shell layer.

In some embodiments of the present invention, the semiconducting light emitting nanoparticle can further comprise one or more additional shell layers onto the 2^{nd} shell layer as a multishell.

According to the present invention, the term “multishell” stands for the stacked shell layers consisting of three or more shell layers.

For example, CdSe/CdS, CdSeS/CdZnS, CdSeS/CdS/ZnS, ZnSe/CdS, CdSe/ZnS, InP/ZnS, InP/ZnSe, InP/ZnSe/ZnS, InZnP/ZnS, InZnP/ZnSe, InZnP/ZnSe/ZnS, InGaP/ZnS, InGaP/ZnSe, InGaP/ZnSe/ZnS, InZnPS/ZnS, InZnPS ZnSe, InZnPS/ZnSe/ZnS, ZnSe/CdS, ZnSe/ZnS or combination of any of these, can be used. Preferably, InP/ZnS, InP/ZnSe, InP/ZnSe/ZnS, InZnP/ZnS, InZnP/ZnSe, InZnP/ZnSe/ZnS, InGaP/ZnS, InGaP/ZnSe, InGaP/ZnSe/ZnS.

Such semiconducting light emitting nanoparticles are publicly available (for example from Sigma Aldrich) and/or can be synthesized with the method described for example in U.S. Pat. Nos. 7,588,828 B, 8,679,543 B and Chem. Mater. 2015, 27, pp 4893-4898.

In some embodiments of the present invention, the composition comprises two or more semiconducting light emitting nanoparticles.

In some embodiments of the present invention, the composition comprises a plurality of semiconducting light emitting nanoparticles.

In some embodiments of the present invention, the total amount of the semiconducting light emitting nanoparticles is in the range from 0.1 wt. % to 90 wt. % based on the total amount of the composition, preferably from 10 wt. % to 70 wt. %, more preferably from 15 wt. % to 50 wt. %.

### —Ligands

In some embodiments of the present invention, optionally, the light emitting moiety can be directly over coated by one or more ligands, or the outer most surface of the inorganic part of the semiconducting light emitting nanoparticle can be directly coated by the ligands. As an option, ligand coated semiconducting light emitting nanoparticle can be overcoated by a polymer forming a polymer beads having said semiconducting light emitting nanoparticle(s) inside.

As the ligands, phosphines and phosphine oxides such as Trioctylphosphine oxide (TOPO), Trioctylphosphine (TOP), and Tributylphosphine (TBP); phosphonic acids such as Dodecylphosphonic acid (DDPA), Tridecylphosphonic acid (TDPA), Octadecylphosphonic acid (ODPA), and Hexylphosphonic acid (HPA); amines such as Oleylamine, Dedecyl amine (DDA), Tetradecyl amine (TDA), Hexadecyl amine (HDA), and Octadecyl amine (ODA), Oleylamine (OLA), 1-Octadecene (ODE), thiols such as hexadecane thiol and hexane thiol; mercapto carboxylic acids such as mercapto propionic acid and mercaptoundecanoicacid; carboxylic acids such as oleic acid, stearic acid, myristic acid; acetic acid, Polyethylenimine (PEI), monofunctional PEG thiol (mPEG-thiol) or a derivatives of mPEG thiol and a combination of any of these can be used.

Examples of such ligands have been described in, for example, the laid-open international patent application No. WO 2012/059931A.

### —Use of the Composition

In another aspect, the present invention relates to use of the composition of the present invention, in an electronic device, optical device, sensing device or in a biomedical device or for fabricating an electronic device, sensing device, optical device or a biomedical device.

### A Layer Containing the Composition and a Process of Fabricating the Layer

In another aspect, the present invention relates to a layer containing the composition of the present invention.

In another aspect, the present invention relates to a layer containing at least, essentially consisting of or consisting of;
I) a (meth)acrylate polymer, preferably it is obtained or obtainable from the preferably it is obtained or obtainable from the reactive monomers in the composition of the present invention;
II) a light emitting moiety; and
iii) a chemical compound comprising at least one group selected from unsaturated straight-chain alkyl group having carbon atoms 1 to 45; unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂ preferably one or more non-adjacent CH₂ groups is replaced by oxygen atom; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
preferably said group is selected from unsaturated straight-chain alkyl group having carbon atoms 1 to 45, unsaturated or saturated branched chain alkyl group having carbon atoms 3 to 45, straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
more preferably it is selected from unsaturated or saturated branched chain alkyl group having carbon atoms 3 to 45 or unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said carbon atoms of the alkyl group, the alkenyl group and/or the alkoxy group are in the range from 10 to 35, more preferably it is from 14 to 30,
furthermore preferably it is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said chain contains 1 to 5 carbon-carbon double bonds, more preferably 1 to 3 carbon-carbon double bonds, even more preferably 2 carbon-carbon double bonds,
wherein said chemical compound is not a polymer.

In a preferable embodiment, the layer thickness of the layer is in the range from 1 to 50 um, preferably from 5 to 30, more preferably from 8 to 20, further more preferably from 10 to 15 um.

In another aspect, the present invention relates to a process of fabricating the layer of the present invention, wherein the process comprises at least, essentially consisting of or consisting of the following steps;
I) providing a composition of the present invention onto a substrate, preferably
II) curing the composition, preferably said curing is performed by photo irradiation and/or thermal treatment.

In another aspect, the present invention relates to a layer obtained or obtainable from the process.

### —Color Conversion Device (100)

A color conversion device (100) comprising at least a 1^{st} pixel (161) partly or fully filled with the layer of any one of claims 20 to 22 and 24 comprising at least a matrix material (120) containing a light emitting moiety (110), and a bank (150) comprising at least a polymer material, preferably the color conversion device (100) further contains a supporting medium (170).

### —1^{st} Pixel (161)

According to the present invention, said 1^{st} pixel (161) comprises at least a matrix material (120) containing a light emitting moiety (110). In a preferable embodiment, the 1^{st} pixel (161) is a solid layer obtained or obtainable by curing the composition of the present invention containing at least one acrylate monomer together with at least one light emitting moiety (110), preferably said curing is a photo curing by photo irradiation, thermal curing or a combination of a photo curing and a thermal curing.

In some embodiments of the present invention, the layer thickness of the pixel (161) is in the range from 0.1 to 100 μm, preferably it is from 1 to 50 μm, more preferably from 5 to 25 μm.

In some embodiments of the present invention, the color conversion device (100) further contains a 2^{nd} pixel (162), preferably the device (100) contains at least said 1^{st} pixel (161), 2^{nd} pixel (162) and a 3^{rd} pixel (163), more preferably said 1^{st} pixel (161) is a red color pixel, the 2^{nd} pixel (162) is a green color pixel and the 3^{rd} pixel (163) is a blue color pixel, even more preferably the 1^{st} pixel (161) contains a red light emitting moiety (110R), the 2^{nd} color pixel (162) contains a green light emitting moiety (110G) and the 3^{rd} pixel (163) does not contain any light emitting moiety.

In some embodiments, at least one pixel (160) additionally comprises at least one light scattering particle (130) in the matrix material (120), preferably the pixel (160) contains a plurality of light scattering particles (130).

In some embodiments of the present invention, said 1^{st} pixel (161) consists of one pixel or two or more sub-pixels configured to emit red-color when irradiated by an excitation light, more preferably said sub-pixels contains the same light emitting moiety (110).

### —Matrix Material (120)

In a preferable embodiment, the matrix material (120) contains a (meth)acrylate polymer, preferably it is a methacrylate polymer, an acrylate polymer or a combination of thereof, more preferably it is an acrylate polymer, even more preferably said matrix material (120) is obtained or obtainable from the composition of the present invention containing at least one acrylate monomer, further more preferably said matrix material (120) is obtained or obtainable from the composition of the present invention containing at least one di-acrylate monomer, particularly preferably said matrix material (120) is obtained or obtainable from the composition of the present invention containing at least one di-acrylate monomer and a monoacrylate monomer, preferably said composition is a photosensitive composition.

### —Bank (150)

In some embodiments of the present invention, the height of the bank (150) is in the range from 0.1 to 100 μm, preferably it is from 1 to 50 μm, more preferably from 1 to 25 μm, furthermore preferably from 5 to 20 μm.

In a preferred embodiment of the present invention, the bank (150) is configured to determine the area of said 1^{st} pixel (161) and at least a part of the bank (150) is directly contacting to at least a part of the 1^{st} pixel (161), preferably said 2^{d} polymer of the bank (150) is directly contacting to at least a part of the 1^{st} polymer of the 1^{st} pixel (161).

More preferably, said bank (150) is photolithographically patterned and said 1^{st} pixel (161) is surrounded by the bank (150), preferably said 1^{st} pixel (161), the 2^{rd} pixel (162) and the 3^{rd} pixel (163) are all surrounded by the photolithographically patterned bank (150).

### —Process

In another aspect, the invention also relates to a process for fabricating the composition of the present invention comprising at least, essentially consisting or consisting of, the following steps Y1 and Y2, preferably in this sequence or Y3;
Y1) mixing at least one light emitting moiety and a reactive monomer to form a 1^{st} composition;
Y2) mixing the 1^{st} composition with a chemical compound comprising at least one group selected from unsaturated straight-chain alkyl group having carbon atoms 1 to 45; unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
preferably said group is selected from unsaturated straight-chain alkyl group having carbon atoms 1 to 45, unsaturated or saturated branched chain alkyl group having carbon atoms 3 to 45, straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
more preferably it is selected from unsaturated or saturated branched chain alkyl group having carbon atoms 3 to 45 or unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said carbon atoms of the alkyl group, the alkenyl group and/or the alkoxy group are in the range from 10 to 35, more preferably it is from 14 to 30,
furthermore preferably it is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said chain contains 1 to 5 carbon-carbon double bonds, more preferably 1 to 3 carbon-carbon double bonds, even more preferably 2 carbon-carbon double bonds,
wherein said chemical compound is not a polymer; or
Y3) mixing at least one light emitting moiety and a reactive monomer with a chemical compound comprising at least one group selected from unsaturated straight-chain alkyl group having carbon atoms 1 to 45; unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
preferably said group is selected from unsaturated straight-chain alkyl group having carbon atoms 1 to 45, unsaturated or saturated branched chain alkyl group having carbon atoms 3 to 45, straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
more preferably it is selected from unsaturated or saturated branched chain alkyl group having carbon atoms 3 to 45 or unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said carbon atoms of the alkyl group, the alkenyl group and/or the alkoxy group are in the range from 10 to 35, more preferably it is from 14 to 30,
furthermore preferably it is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂,
preferably one or more non-adjacent CH₂ groups is replaced by oxygen atom;
preferably said chain contains 1 to 5 carbon-carbon double bonds, more preferably 1 to 3 carbon-carbon double bonds, even more preferably 2 carbon-carbon double bonds,
wherein said chemical compound is not a polymer.

In a preferable embodiment of the present invention, the method comprises a purification step of the reactive monomers. More preferably, said purification step is taken place before step Y1) and/or Y0).

More details of the composition such as “reactive monomer”, “light emitting moiety” and “chemical compound” are described above such as in the section of “reactive monomer”, “light emitting moiety” and “chemical compound”.

Additional additives as described in the section of “additional material” can be mixed.

In another aspect, the present invention also relates to a method for fabricating a color conversion device (100) of the present invention, containing at least the following steps, preferably in this sequence;
Xi) Providing a bank composition onto a surface of a supporting medium
Xii) Curing the bank composition,
Xiii) Applying photo-patterning to the cured said composition to fabricate bank and a patterned pixel region,
Xiv) Providing the composition of the present invention to at least one pixel region, preferably by ink-jetting,
Xv) Curing the composition, preferably said color conversion device (100) further contains a supporting medium (170).

In another aspect, the present invention further relates to a color conversion device (100) obtainable or obtained from the method of the present invention.

In another aspect, the present invention further relates to use of the color conversion device (100) of the present invention in an optical device (300) containing at least one functional medium (320, 420, 520) configured to modulate a light or configured to emit light.

Further, in another aspect, the present invention further relates to an optical device (300) containing at least one functional medium (320, 420, 520) configured to modulate a light or configured to emit light, and the color conversion device (100) of the present invention.

### Preferable Embodiments

1. A composition, preferably it is being of a photocurable composition, comprising at least;
i) a reactive monomer, preferably said monomer having one or more of functional groups, more preferably it is a (meth)acrylate monomer;
ii) a light emitting moiety; and
iii) a chemical compound comprising at least one group selected from unsaturated straight-chain alkyl group having carbon atoms 1 to 45; unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
preferably said group is selected from unsaturated straight-chain alkyl group having carbon atoms 1 to 45, unsaturated or saturated branched chain alkyl group having carbon atoms 3 to 45, straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
more preferably it is selected from unsaturated or saturated branched chain alkyl group having carbon atoms 3 to 45 or unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said carbon atoms of the alkyl group, the alkenyl group and/or the alkoxy group are in the range from 10 to 35, more preferably it is from 14 to 30,
furthermore preferably it is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said chain contains 1 to 5 carbon-carbon double bonds, more preferably 1 to 3 carbon-carbon double bonds, even more preferably 2 carbon-carbon double bonds,
wherein said chemical compound is not a polymer.

2. The composition of embodiment 1, wherein said chemical compound further comprises at least one group selected from one or more of members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid, preferably said group is a phosphate group, a phosphonate group, thiol group, a carboxyl group or a combination of any of these, more preferably it is a carboxyl group.

3. The composition of embodiment 1 or 2, wherein the chemical compound is represented by following chemical formula (X^{A}).

Z(—X)u-Y (X^{A})
wherein Z is *—R^{x1} or

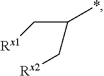

where “*” represents the connecting point to symbol Y of the formula, R^{x1} is a group selected from one or more members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid, preferably said group is a phosphonate group, thiol group, a carboxyl group or a combination of any of these, more preferably it is a carboxyl group; and
R^{x2} is a group selected from one or more of members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid, preferably said group is a phosphonate group, thiol group, a carboxyl group or a combination of any of these, more preferably it is a carboxyl group;
X is a single bond, an alkylene group having 1 to 15 carbon atoms, or an alkenylene group having 1 to 15 carbon atoms, or (poly)alkoxylene group having 1 to 15 carbon atoms, preferably Y is an (poly)alkoxylene group having 1 to 15 carbon atoms;
u is 0 or 1;
Y is selected from unsaturated straight-chain alkyl group having carbon atoms 1 to 45, unsaturated or saturated branched chain alkyl group having carbon atoms 3 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom; straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight chain aryl-alkyl group having carbon atoms 4 to 45, unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
preferably said group is selected from unsaturated straight-chain alkyl group having carbon atoms 1 to 45, unsaturated or saturated branched chain alkyl group having carbon atoms 3 to 45, straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
more preferably it is selected from unsaturated or saturated branched chain alkyl group having carbon atoms 3 to 45 or unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said carbon atoms of the alkyl group, the alkenyl group and/or the alkoxy group are in the range from 10 to 35, more preferably it is from 14 to 30,
furthermore preferably it is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said chain contains 1 to 5 carbon-carbon double bonds, more preferably 1 to 3 carbon-carbon double bonds, even more preferably 2 carbon-carbon double bonds,
said alkyl group, alkenyl group and/or alkoxy group, may optionally be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂, preferably Y is a straight-chain or branched alkyl group,
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another;

In case Y is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom, preferably u is 1 and Y is represented by the following formula,

*—[CH(R¹)—CH(R²)-Q]ₓR³,
wherein R¹ is H or an alkyl group having carbon atoms 1 to 5, preferably said alkyl group is an methyl group; R² is H or an alkyl group having carbon atoms 1 to 5, preferably said alkyl group is an methyl group, Q is an oxygen atom, nitrogen atom or sulfur atom, preferably Q is an oxygen atom; R³ is H or a methyl group, x is an integer, preferably x is in the range from 1 to 300, more preferably from 2 to 200, even more preferably from 4 to 100, where “*” represents the connecting point to symbol X of the formula;
or

*—[(CHR¹)ₙ-Q)]ₓ-R³
wherein n is 2 or 3, Q is an oxygen atom, nitrogen atom or sulfur atom, preferably Q is an oxygen atom, R¹ is H or a methyl group, R³ is H or a methyl group, n is 1 to 5, preferably 1 to 3, more preferably n is 2, x is an integer, preferably x is in the range from 1 to 300, more preferably from 2 to 200, even more preferably from 4 to 100, where “*” represents the connecting point to symbol X of the formula, and
preferably wherein Z represents an attaching group comprising one or two atoms or Z is a carboxyl group, preferably Z is

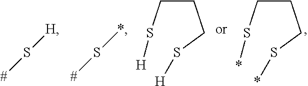

more preferably

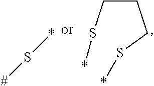

where “#” represents the connecting point to group X, and “*” represents the connecting point to the surface of the light emitting moiety.

4. The composition of any one of embodiments 1 to 3, wherein the ratio of the total weight of the chemical compound to the total weight of the light emitting moiety is in the range 0.6:40 to 1:3, preferably it is from 1:40 to 1:2, more preferably from 1.5:40 to 1:1; in case of said light emitting moiety is an inorganic light emitting material, the ratio of the weight of the chemical compound to the weight of the inorganic part of the inorganic light luminescent material is in the range from 0.003 to 3.2, preferably from 0.006 to 2.8, more preferably from 0.015 to 1.3.

5. The composition of any one of embodiments 1 to 4, wherein the light emitting moiety contains at least one ligand, preferably said ligand is different from said chemical compound, preferably said ligand comprises at least one straight-chain or branched chain alkyl group having carbon atoms 1 to 45, straight-chain or branched chain alkenyl group having carbon atoms 1 to 45 or straight-chain or branched chain alkoxyl group having carbon atoms 1 to 45, more preferably said ligand contains a saturated straight-chain alkyl group having carbon atoms 1 to 45.

6. The composition of any one of embodiments 1 to 5, wherein the average diameter of the inorganic part of the light emitting moiety is in the range from 1 nm to 18 nm, preferably it is from 2 to 15 nm, more preferably it is from 4 to 12 nm, preferably said light emitting moiety is configured to emit light having peak maximum light wavelength in the range from 400 to 900, more preferably from 500 to 850 nm, even more preferably from 515 to 820 nm, (will move to specification (description) 590 nm to 800 nm).

7. The composition of any one of embodiments 1 to 6, wherein said reactive monomer is a (meth)acrylate monomer selected from a mono-(meth)acrylate monomer, a di-(meth)acrylate monomer or a tri-(meth)acrylate monomer more preferably it is a di-methacrylate monomer or a di-acrylate monomer, tri-methacrylate monomer, tri-acrylate monomer, even more preferably it is represented by following chemical formula (II);

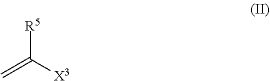

X³ is a non-substituted or substituted alkyl group, aryl group or an alkoxy group;
preferably the symbol X³ is

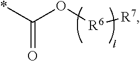

where “*” on the left side of the formula represents the connecting point to the end group C═CR⁵ of the formula (I);
I is 0 or 1;
R⁵ is a hydrogen atom, halogen atom of Cl, Br, or F, methyl group, alkyl group, aryl group, alkoxy group, ester group, or a carboxylic acid group;
R⁶ is a straight alkylene chain or alkoxylene chain having 1 to 25 carbon atoms, preferably R⁶ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R⁷ is a straight alkylene chain or alkoxylene chain having 1 to 25 carbon atoms, preferably R⁷ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another.

8. The composition of any one of embodiments 1 to 7, further comprises a (meth)acrylate monomer represented by following chemical formula (I) and/or a (meth)acrylate monomer represented by following chemical
formula (III);

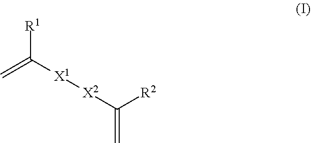

wherein
X¹ is a non-substituted or substituted alkyl group, aryl group or an alkoxy group or an ester group;
X² is a non-substituted or substituted alkyl group, aryl group or an alkoxy group or an ester group;
R¹ is a hydrogen atom, halogen atom of Cl, Br, or F, methyl group, alkyl group, aryl group, alkoxy group, ester group, or a carboxylic acid group;
R² is a hydrogen atom, halogen atom of Cl, Br, or F, methyl group, alkyl group, aryl group, alkoxy group, ester group, or a carboxylic acid group;
preferably the symbol X¹ is

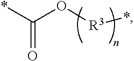

where “*” on the left side of the formula represents the connecting point to the carbon atom of the end group C═CR¹ of the formula (I) and “*” on the right side represents the connecting point to symbol X² of the formula (I); n is 0 or 1;
preferably the symbol X² is

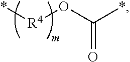

where “*” on the left side of the formula represents the connecting point to symbol X1 of the formula (I) and “*” on the right side represents the connecting point to the end group C═CR² of the formula (I);
m is 0 or 1;
preferably at least m or n is 1;
R³ is a straight alkylene chain or alkoxylene chain having 1 to 25 carbon atoms, a cycloalkane having 3 to 25 carbon atoms or an aryl group having 3 to 25 carbon atoms, preferably R³ is a straight alkylene chain or alkoxylene chain having 1 to 15 carbon atoms, more preferably 1 to 5 carbon atoms,
which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R⁴ is a straight alkylene chain or alkoxylene chain having 1 to 25 carbon atoms, a cycloalkane having 3 to 25 carbon atoms or an aryl group having 3 to 25 carbon atoms, preferably R⁴ is a straight alkylene chain or alkoxylene chain having 1 to 15 carbon atoms, more preferably 1 to 5 carbon atoms,
which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another;

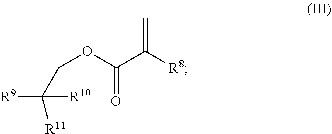

wherein R⁹ is hydrogen atom, a straight alkyl group having 1 to 25 carbon atoms or a (meth)acryl group represented by chemical formula (IV)

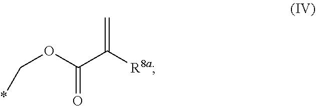

R¹⁰ is hydrogen atom, a straight alkyl group having 1 to 25 carbon atoms or a (meth)acryl group represented by chemical formula (V)

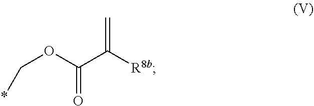

R¹¹ is hydrogen atom, a straight alkyl group having 1 to 25 carbon atoms or a (meth)acryl group represented by chemical formula (VI)

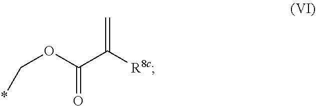

wherein R^{8a}, R^{8b} and R^{8c} are, each independently or dependently of each other at each occurrence, H or CH₃;
wherein at least one of R⁹, R¹⁰ and R¹¹ is a (meth)acryl group, preferably two of R⁹, R¹⁰ and R¹¹ are a (meth)acryl group and other one is a hydrogen atom or a straight alkyl group having 1 to 25 carbon atoms, preferably the electric conductivity (S/cm) of the (meth)acrylate monomer of formula (III) is 1.0*10⁻¹⁰ or less, preferably it is 5.0*10⁻¹¹ or less, more preferably it is in the range from 5.0*10⁻¹¹ to 1.0*10⁻¹⁵, even more preferably it is in the range from 5.0*10⁻¹ to 1.0*10⁻¹⁵.

9. The composition of any one of embodiments 1 to 8, wherein the (meth)acrylate monomer of chemical formula (II) is in the composition and the mixing ratio of the (meth)acrylate monomer of chemical formula (I) to the (meth)acrylate monomer of chemical formula (II) is in the range from 1:99 to 99:1 (formula (I): formula (II)), preferably from 5:95 to 50:50, more preferably from 10:90 to 40:60, even more preferably it is from 15:85 to 35:65, preferably at least a purified (meth)acrylate monomer represented by chemical formula (I), (II) is used in the composition, more preferably the (meth)acrylate monomer of chemical formula (I) and the (meth)acrylate monomer of chemical formula (II) are both obtained or obtainable by a purification method.

10. The composition of any one of embodiments 1 to 9, wherein the boiling point (B.P.) of said (meth)acrylate monomer of chemical formula (I) and/or chemical formula (II) is 250° C. or more, preferably the (meth)acrylate monomers of chemical formula (I) and chemical formula (II) are both 250° C. or more, more preferably it is in the range from 250° C. to 350° C., even more preferably from 280° C. to 350° C., further more preferably from 300° C. to 348° C.

11. The composition of any one of embodiments 1 to 10, wherein said light emitting moiety is an organic light emitting moiety and/or inorganic light emitting moiety, preferably it is an inorganic light emitting moiety, more preferably it is an inorganic light emitting moiety is an inorganic phosphor or a quantum material, preferably said light emitting moiety contains a ligand attached onto the outer most surface of the light emitting moiety.

12. The composition of any one of embodiments 1 to 11, wherein the total amount of the light emitting moiety is in the range from 0.1 wt. % to 90 wt. % based on the total amount of the composition, preferably from 10 wt. % to 70 wt. %, more preferably from 15 wt. % to 50 wt. %.

13. The composition of any one of claims 1 to 12, wherein the viscosity of the composition is 35 cP or less at room temperature, preferably in the range from 1 to 35 cP, more preferably from 2 to 30 cP, even more preferably from 2 to 25 cP.

14. The composition of any one of embodiments 1 to 13, comprises an another material selected from one or more members of the group consisting of:
iii) another light emitting moiety which is different from the light emitting moiety of embodiment 1, preferably said light emitting moiety comprises a ligand, more preferably said light emitting moiety comprises an alkyl type ligand having carbon atoms 2 to 25;
iv) another (meth)acrylate monomer;
v) scattering particles, and
vi) optically transparent polymers, antioxidants, radical quenchers, photo initiators and/or surfactants.

15. The composition of any one of embodiments 1 to 14, comprises v) scattering particles; and
vii) at least one polymer configured so that said polymer enables to the scattering particles to be dispersed in the composition;
wherein the polymer comprises at least a phosphine group, phosphine oxide group, phosphate group, phosphonate group, thiol group, tertiary amine, carboxyl group, hetero cyclic group, silane group, sulfonic acid, hydroxyl group, phosphonic acid, or a combination of thereof, preferably the polymer comprises a tertiary amine, phosphine oxide group, phosphonic acid, or a phosphate group.

16. The composition of any one of embodiments 1 to 15, the composition is configured to show the EQE value 23% or more, preferably 24% or more and less than 95%, preferably less than 50%.

17. The composition of any one of embodiments 1 to 16, wherein the composition comprises a solvent 10 wt % or less based on the total amount of the composition, more preferably it is 5 wt % or less, more preferably it is a solvent free composition, preferably the composition does not comprise any one of the following solvent selected from one or more members of the group consisting of ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; propylene glycol monoalkyl ethers, such as, propylene glycol monomethyl ether (PGME), propylene glycol monoethyl ether, and propylene glycol monopropyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, triethylene glycol and glycerin; esters, such as, ethyl 3-ethoxypropionate, methyl 3-methoxypropionate and ethyl lactate; and cyclic asters, such as, gamma-butyro-lactone; chlorinated hydrocarbons, such as chloroform, dichloromethane, chlorobenzene, trimethyl benzenes such as 1,3,5-trimethylbenzene, 1,2,4-trimethyl benzene, 1,2,3-trimethyl benzene, docecylbenzene, cyclohexylbenzene, 1,2,3,4-tetramethylbenzene, 1,2,3,5-tetramethylbenzene, 3-isopropylbiphenyl, 3-methylbiphenyl, 4-methylbiphenyl and dichlorobenzene, preferably said solvent is propylene glycol alkyl ether acetates, alkyl acetates, ethylene glycol monoalkyl ethers, propylene glycol, and propylene glycol monoalkyl ethers.

18. The composition of any one of embodiments 1 to 17, comprises at least the (meth)acrylate monomer of chemical formula (I), the (meth)acrylate monomer of chemical formula (II) and the polymer configured so that said polymer enables to the scattering particles to be dispersed in the composition, wherein the mixing ratio of the (meth)acrylate monomer of chemical formula (I): the (meth)acrylate monomer of chemical formula (II): the polymer is 10:89:1 to 50:40:10, preferably in the range from 15:82:3 to 30:60:10.

19. A composition comprising a polymer derived or derivable from one or more of the reactive monomers of the composition of any one of embodiments 1 to 18, preferably it is obtained or obtainable by curing the composition.

20. A layer containing at least;
I) a (meth)acrylate polymer, preferably it is obtained or obtainable from the reactive monomers in the composition of any one of embodiments 1 to 18;
II) a light emitting moiety; and
iii) a chemical compound comprising at least one group selected from unsaturated straight-chain alkyl group having carbon atoms 1 to 45; unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
preferably said group is selected from unsaturated straight-chain alkyl group having carbon atoms 1 to 45, unsaturated or saturated branched chain alkyl group having carbon atoms 3 to 45, straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
more preferably it is selected from unsaturated or saturated branched chain alkyl group having carbon atoms 3 to 45 or unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said carbon atoms of the alkyl group, the alkenyl group and/or the alkoxy group are in the range from 10 to 35, more preferably it is from 14 to 30,
furthermore preferably it is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said chain contains 1 to 5 carbon-carbon double bonds, more preferably 1 to 3 carbon-carbon double bonds, even more preferably 2 carbon-carbon double bonds,
wherein said chemical compound is not a polymer.

21. A color conversion device (100) comprising at least a 1^{st} pixel (161) partly or fully filled with the layer of claim 20 comprising at least a matrix material (120) containing a light emitting moiety (110), and a bank (150) comprising at least a polymer material, preferably the color conversion device (100) further contains a supporting medium (170).

22. An optical device (300) containing at least one functional medium (320, 420, 520) configured to modulate a light or configured to emit light, and the color conversion device (100) of embodiment 21.

### Technical Effects of the Invention

Improved homogeneous dispersion of light emitting moieties in the composition, improved homogeneous dispersion of scattering particles in the composition, preferably improved homogeneous dispersion of both light emitting particles and scattering particles, more preferably improved homogeneous dispersion of light emitting moieties and/or scattering particles without solvent; composition having lower viscosity suitable for inkjet printing, no increasement with time of viscosity of composition, preferably a composition which can keep lower viscosity even if it is mixed with high loading of light emitting moieties and/or scattering particles, even more preferably without solvent; composition having lower vapor pressure for large area uniform printing; a new composition realizing no residue around ink jet printing nozzle during/after ink jet printing, improved QY and/or EQE of light emitting moieties in the composition, improved QY and/or EQE of light emitting moieties after printing; improved thermal stability; easy printing without clogging at a printing nozzle; easy handling of the composition, improved printing properties; simple fabrication process; improved absorbance of blue light; improved solidity of a later made from the composition after inkjet printing.

The working examples 1-13 below provide descriptions of the present invention, as well as an in-detail description of their fabrication.

### WORKING EXAMPLES

mPEG350-SH: poly(ethylene glycol) methyl ether thiol, average Mn 350
mPEG800-SH: poly(ethylene glycol) methyl ether thiol, average Mn 800
LA: lauryl acrylate
HDDA: 1,6-hexanediol diacrylate

### Working Example 1: Preparation of Matrix

To 0.04 g of Irganox™819 is added 2.368 g of LA and 0.592 g of HDDA. The mixture is shaken until complete dissolution of Irganox™ 819.

### Comparative Example 1: Preparation of Red QD Ink

0.75 g of matrix obtained in example 1, 0.25 g of InP based red QD (core-double shells) having dodecyl group as a ligand dispersed in heptane are mixed in a glass flask and volatiles are evaporated on rotary evaporator under vacuum at 30 deg. C. Remaining volatiles are removed under vacuum of 60 mTorr on a Schlenk line.

### Working Example 2: Preparation of Red QD Ink with mPEG350-SH

0.05 g of mPEG350-SH is dissolved in 1 mL of toluene, 0.25 g of InP based red QD having dodecyl group as a ligand dispersed in heptane is added and the mixture is stirred for 1.5 hrs. Then 0.7 g of matrix obtained in example 1 is added, volatiles are evaporated on rotary evaporator under vacuum at 30 deg. C. Remaining volatiles are removed under vacuum of 60 mTorr on a Schlenk line.

### Working Example 3: Preparation of Red QD Ink with mPEG800-SH

Red QD ink with mPEG800-SH is prepared in the same manner as described in working example 2 above except for that mPEG800-SH is used instead of mPEG350-SH.

### Working Example 4: Ligand Exchange on Red QD with Linoleic Acid (Linoleic Acid/QD_{inorg.} Weight Ratio=0.2)

4.88 g of InP based red QD having dodecyl group as a ligand dispersed in heptane is put in a glass flask, 5.33 g of anhydrous THF is added, 0.2 g of linoleic acid is added, the mixture is flashed with Ar and refluxed for 2 h under Ar. After cooling down the solution the red QD is precipitated out by adding 60 ml of dry iso-propanol. Then the turbid solution is centrifuged at 2950 G for 5 min, and supernatant is decanted. Then 3.82 g of dry n-heptane is added to prepare stock solution in n-heptane of 188 mg/mL QDs concentration.

### Working Example 5: Ligand Exchange on Red QD with Elaidic Acid (Elaidic Acid/QD_{inorg.} Weight Ratio=1.4)

Red QD with elaidic acid is prepared in the same manner as described in working example 4 above except for that 1.4 g of elaidic acid are used.

### Working Example 6: Ligand Exchange on Red QD with Isostearic Acid (Isostearic Acid/QD_{inorg.} Weight Ratio=1.4)

Red QD ink with isostearic acid is prepared in the same manner as described in working example 4 above except for that 1.4 g of isostearic acid are used.

### Working Example 7: Ligand Exchange on Red QD with mPEG350-SH (mPEG350-SH/QD_{inorg.} m. Weight Ratios=0.05-0.4)

9.76 g of InP based red QD having dodecyl group as a ligand dispersed in heptane is put in a glass flask, 10 mL of anhydrous THF is added, the mixture is flashed with Ar and refluxed for 1 hour under Ar. Then a solution of 0.08 g of mPEG350-SH in THF/n-heptane 0.5 mL/0.5 mL is added, the reaction mixture is refluxed for 1 h under Ar. After cooling down, 4 mL of the reaction mixture is removed and purified separately. To the remaining reaction mixture of 0.1 g of mPEG350-SH in THF/n-heptane 0.5 mL/0.5 mL is added, the reaction mixture is for 1 h under Ar. After cooling down, 4 mL of the reaction mixture is removed and purified separately. To the remaining reaction mixture of 0.1 g of mPEG350-SH in THF/n-heptane 0.5 mL/0.5 mL is added, the reaction mixture is for 1 h under Ar. After cooling down, 4 mL of the reaction mixture is removed and purified separately. To the remaining reaction mixture of 0.1 g of mPEG350-SH in THF/n-heptane 0.5 mL/0.5 mL is added, the reaction mixture is for 1 h under Ar. After cooling down the solution the red QD is precipitated out by adding 14 ml of dry n-heptane. Then the turbid solution is centrifuged at 2950 G for 5 min, and supernatant is decanted. Then dry toluene is added to prepare stock solution in toluene of 306 mg/mL QDs concentration.

### Working Example 8: Preparation of Red QD Ink with QD with Linoleic Acid as Ligand Obtained in Working Example 4

0.75 g of matrix obtained in example 1, 0.25 g of InP based red QD dispersed in n-heptane obtained in example 4 are mixed in a glass flask and volatiles are evaporated on rotary evaporator under vacuum at 30 deg. C. Remaining volatiles are removed under vacuum of 60 mTorr on a Schlenk line.

### Working Example 9: Preparation of Red QD Ink with QD with mPEG350-SH as Ligand Obtained in Working Example 7

Same as example 8, but InP based red QD dispersed in toluene obtained in example 7 is used.

### Working Example 10: Preparation of Red QD Ink with QD with Elaidic Acid as Ligand Obtained in Working Example 5

Same as example 8, but suspension of InP based red QD in n-heptane obtained in example 5 is used.

### Working Example 11: Preparation of Red QD Ink with QD with Isostearic Acid as Ligand Obtained in Working Example 6

Same as example 8, but suspension of InP based red QD in n-heptane obtained in example 6 is used.

### Working Example 12: Dispersibility Test

The red QD inks obtained in working example 2, 3, 8, 9, 10, 11, 13 and the red QD ink obtained in comparative example 1 are stored in an atmospheric condition at room temperature.

The red QD inks of working example 2, 3, 8, 9, 10, 11, 13 (especially red QD inks of working example 2, 3, 8, 9, 13) shows excellent dispersibility compared to the comparative example 1 without any additive ligand.

### Working Example 12: Nozzle Plate Wetting Test

Nozzle plate wetting test is performed as described below.

QD inks obtained in working examples 2, 3, 8, 9, 10, 11 and QD ink obtained in comparative example are each separately dropped onto an each nozzle plate of print head (Dimatix DMP-2831 material printer, Fuji film), then the dropped inks are removed by soaking up with the cleaning pad. Cleanness of the surface on the each nozzle plate is observed by eyes.

### Working Example 13: Preparation of Red QD Ink with Linoleic Acid

0.05 g of linoleic acid is dissolved in 1 mL of toluene, 0.25 g of InP based red QD having dodecyl group as a ligand dispersed in heptane is added and the mixture is stirred for 1 hr at 40 deg. C. Then 0.7 g of matrix obtained in example 1 is added, volatiles are evaporated on rotary evaporator under vacuum at 30 deg. C. Remaining volatiles are removed under vacuum of 60 mTorr on a Schlenk line.

### RESULTS

The QD inks 2, 3, 9 are well repelled on the nozzle plate. The surfaces of nozzle plates where QD inks 2, 3, 9 are dropped are very clean after cleaning by the pad. It indicates that during ink jet printing, the ink composition especially QD inks 2, 3, 9 of the present invention can be smoothly ink jetted onto a substrate without causing clogging, without remaining around nozzle of ink jet machine, without remaining on or around the surface of nozzle.

Table 1 shows the results of dispersibility text of working example 12 and nozzle plate wetting text of working example 13.

TABLE 1

| Example | Comparative 1 | 2 | 3 | 8 | 9 | 10 | 11 |
|---|---|---|---|---|---|---|---|
| Dispersion stability | − | ++ | ++ | ++ | ++ | + | + |
| No nozzle plate wetting | − | + | + | −/+ | + | − | − |

1.-15. (canceled)

16. A composition comprising at least;
i) a reactive monomer;
ii) a light emitting moiety; and
iii) a chemical compound comprising at least one group selected from unsaturated straight-chain alkyl group having carbon atoms 1 to 45; unsaturated or saturated straight-chain alkyl group having carbon atoms 1 to 80, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
wherein said chemical compound is not a polymer.

17. The composition of claim 16, wherein said chemical compound further comprises at least one group selected from one or more of members of the group consisting of phosphine group, phosphine oxide group, phosphate group, phosphonate group, thiol group, tertiary amine, carboxyl group, hetero cyclic group, silane group, sulfonic acid, hydroxyl group and phosphonic acid.

18. The composition of claim 16, wherein the chemical compound is represented by following chemical formula (X^{A}).
Z(—X)u-Y (X^{A})
wherein
Z is *—R^{x1} or 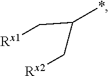
where “*” represents the connecting point to symbol Y of the formula, R^{x1} is a group selected from one or more members of the group consisting of phosphine group, phosphine oxide group, phosphate group, phosphonate group, thiol group, tertiary amine, carboxyl group, hetero cyclic group, silane group, sulfonic acid, hydroxyl group and phosphonic acid; and
R^{x2} is a group selected from one or more of members of the group consisting of phosphine group, phosphine oxide group, phosphate group, phosphonate group, thiol group, tertiary amine, carboxyl group, hetero cyclic group, silane group, sulfonic acid, hydroxyl group and phosphonic acid;
X is a single bond, an alkylene group having 1 to 15 carbon atoms, or an alkenylene group having 1 to 15 carbon atoms, or (poly)alkoxylene group having 1 to 15 carbon atoms;
U is 0 or 1;
Y is selected from a unsaturated straight-chain alkyl group having carbon atoms 1 to 45, unsaturated or saturated branched chain alkyl group having carbon atoms 3 to 45, and/or a unsaturated or saturated straight-chain alkyl group having carbon atoms 1 to 80; said alkyl group, alkenyl group and/or alkoxy group, may optionally be substituted by one or more radicals RV, where one or more non-adjacent CH₂ groups may be replaced by R^{a}C═CR^{a}, C≡C, Si(R)₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂,
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another;
in case Y is an unsaturated or saturated straight-chain alkyl group having carbon atoms 1 to 80, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂.

19. The composition of claim 16, wherein the ratio of the total weight of the chemical compound to the total weight of the light emitting moiety is in the range 0.6:40 to 1:3; in case of said light emitting moiety is an inorganic light emitting material, the ratio of the weight of the chemical compound to the weight of the inorganic part of the inorganic light luminescent material is in the range from 0.003 to 3.2.

20. The composition of claim 16, wherein the light emitting moiety contains at least one ligand.

21. The composition of claim 16, wherein said reactive monomer is a (meth)acrylate monomer is a mono-(meth)acrylate monomer, a di-(meth)acrylate monomer or a tri-(meth)acrylate monomer.

22. The composition of claim 16, further comprises a (meth)acrylate monomer represented by following chemical formula (I) and/or a (meth)acrylate monomer represented by following chemical formula (III); 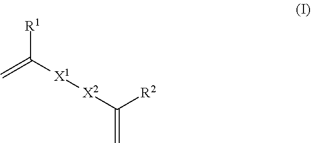
wherein
X¹ is a non-substituted or substituted alkyl group, aryl group or an alkoxy group or an ester group;
X² is a non-substituted or substituted alkyl group, aryl group or an alkoxy group or an ester group;
R¹ is a hydrogen atom, halogen atom of Cl, Br, or F, methyl group, alkyl group, aryl group, alkoxy group, ester group, or a carboxylic acid group;
R² is a hydrogen atom, halogen atom of Cl, Br, or F, methyl group, alkyl group, aryl group, alkoxy group, ester group, or a carboxylic acid group; 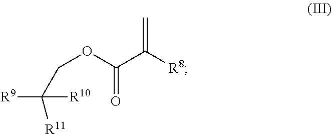
wherein
R⁹ is hydrogen atom, a straight alkyl group having 1 to 25 carbon atoms or a (meth)acryl group represented by chemical formula (IV) 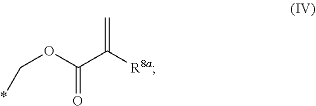
R¹⁰ is hydrogen atom, a straight alkyl group having 1 to 25 carbon atoms or a (meth)acryl group represented by chemical formula (V) 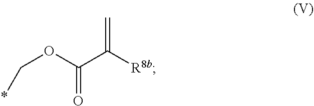
R¹¹ is hydrogen atom, a straight alkyl group having 1 to 25 carbon atoms or a (meth)acryl group represented by chemical formula (VI) 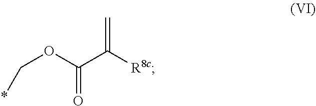
wherein R^{8a}, R^{8b} and R^{8c} are, each independently or dependently of each other at each occurrence, H or CH₃;
wherein at least one of R⁹, R¹⁰ and R¹¹ is a (meth)acryl group.

23. The composition of claim 16, wherein the boiling point (B.P.) of said (meth)acrylate monomer of chemical formula (I) and/or chemical formula (II) is 250° C. or more.

24. The composition of claim 16, wherein the viscosity of the composition is 35 cP or less at room temperature.

25. The composition of claim 16, further comprises another material selected from one or more members of the group consisting of;
iii) another light emitting moiety which is different from the light emitting moiety of claim 16;
iv) another (meth)acrylate monomer;
v) scattering particles, and
vi) optically transparent polymers, antioxidants, radical quenchers, photo initiators and/or surfactants.

26. The composition of claim 16, further comprises another material selected from one or more members of the group consisting of;
v) scattering particles; and
vii) at least one polymer configured so that said polymer enables to the scattering particles to be dispersed in the composition;
wherein the polymer comprises at least a phosphine group, phosphine oxide group, phosphate group, phosphonate group, thiol group, tertiary amine, carboxyl group, hetero cyclic group, silane group, sulfonic acid, hydroxyl group, phosphonic acid or a combination of thereof.

27. The composition of claim 16, wherein the composition comprises a solvent 10 wt % or less based on the total amount of the composition.

28. A composition comprising a polymer derived or derivable from one or more of the reactive monomers of the composition of claim 16.

29. A layer containing at least;
I) a (meth)acrylate polymer;
II) a light emitting moiety; and
III) a chemical compound comprising at least one group selected from unsaturated straight-chain alkyl group having carbon atoms 1 to 45; unsaturated or saturated straight-chain alkyl group having carbon atoms 1 to 80, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂; unsaturated or saturated branched chain alkyl group having carbon atoms 3 to 45; straight-chain alkenyl group having carbon atoms 2 to 45; branched chain alkenyl group having carbon atoms 3 to 45; unsaturated or saturated straight-chain or branched chain alkoxyl group having carbon atoms 1 to 45; unsaturated or saturated straight chain aryl-alkyl group having carbon atoms 4 to 45; unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
wherein said chemical compound is not a polymer.

30. A color conversion device comprising at least a 1^{st} pixel partly or fully filled with the layer of claim 29 comprising at least a matrix material containing a light emitting moiety, and a bank comprising at least a polymer material.

31. A color conversion device as claimed 30, further comprising a supporting medium.

32. An optical device containing at least one functional medium configured to modulate a light or configured to emit light, and the color conversion device of any one of claim 30.
